(19) United States
(12) Patent Application Publication
(10) Pub. No.: US 2009/0000222 A1
(43) Pub. Date: Jan. 1, 2009

(54) Photovoltaic Roofing Tiles And Methods For Making Them

(76) Inventors: Husnu M. Kalkanoglu, Swarthmore, PA (US); Wayne E. Shaw, Glen Mills, PA (US); Ming-Liang Shiao, Collegeville, PA (US)

Correspondence Address: MCDONNELL BOEHNEN HULBERT & BERGHOFF LLP, 300 S. WACKER DRIVE, 32ND FLOOR, CHICAGO, IL, 60606, US

(21) Appl. No.: 12/146,986

(22) Filed: Jun. 26, 2008

Related U.S. Application Data
(60) Provisional application No. 60/946,902, filed on Jun. 28, 2007.
(60) Provisional application No. 60/986,219, filed on Nov. 7, 2007.

(51) Int. Cl. E04D 13/18; H01L 31/042; H01L 31/18

(52) U.S. Cl. 52/173.3; 136/244; 264/241

(57) ABSTRACT

The present invention relates to photovoltaic roofing tiles and methods of manufacturing them. One aspect of the present invention is a photovoltaic roofing tile comprising: a polymeric carrier tile having a top surface and a bottom surface; and a photovoltaic element affixed to the polymeric carrier tile, the photovoltaic element having a bottom surface and a top surface having an active area. Another aspect of the invention is a method of making a photovoltaic roofing tile comprising inserting into a compression mold a polymeric tile preform having a top surface and a bottom surface, and a photovoltaic element, a surface of the photovoltaic element being disposed adjacent to a surface of the polymeric tile preform; compression molding the polymeric tile preform and the photovoltaic element together to form an unfinished photovoltaic roofing tile; and finishing the unfinished photovoltaic roofing tile to provide the photovoltaic roofing tile.

### CROSS-REFERENCE TO RELATED APPLICATIONS

The present application claims priority under 35 U.S.C. §119(e) to U.S. Provisional Patent Application Ser. No. 60/946,902, filed Jun. 28, 2007, and to U.S. Provisional Patent Application Ser. No. 60/986,219, filed Nov. 7, 2007, each of which is incorporated by reference in its entirety in its entirety.

### BACKGROUND OF THE INVENTION

1. Field of the Invention

The present invention relates generally to photovoltaic power generation. The present invention relates more particularly to photovoltaic roofing tiles.

2. Technical Background

The search for alternative sources of energy has been motivated by at least two factors. First, fossil fuels have become more and more expensive due to increasing scarcity and unrest in areas rich in petroleum deposits. Second, there exists overwhelming concern about the effects of the combustion of fossil fuels on the environment, due to factors such as air pollution (from NOₓ, hydrocarbons and ozone) and global warming (from CO₂). In recent years, research and development attention has focused on harvesting energy from natural environmental sources such as wind, flowing water and the sun. Of the three, the sun appears to be the most widely useful energy source across the continental United States; most locales get enough sunshine to make solar energy feasible.

Accordingly, there are now available components that convert light energy into electrical energy. Such “photovoltaic cells” are often made from semiconductor-type materials such as doped silicon in either single crystalline, polycrystalline, or amorphous form. The use of photovoltaic cells on roofs is becoming increasingly common, especially as device performance has improved. They can be used, for example, to provide at least a fraction of the electrical energy needed for a building's overall function, or can be used to power one or more particular devices, such as exterior lighting systems. Photovoltaic cells are often provided on a roof in array form.

Often perched on an existing roof in panel form, these photovoltaic arrays can be quite visible and generally not aesthetically pleasant. Nonetheless, to date, installations appear to have been motivated by purely practical and functional considerations; integration between the photovoltaic elements and the rest of a roof structure is generally lacking. Lack of aesthetic appeal is especially problematic in residential buildings with non-horizontally pitched roofs; people tend to put a much higher premium on the appearance of their homes than they do on the appearance of their commercial buildings.

### SUMMARY OF THE INVENTION

The inventors have determined that there remains a need for photovoltaic devices having more controllable and desirable aesthetics for use in roofing applications while retaining sufficient efficiency in electrical power generation. The inventors have also determined that there remains a need for cost-effective manufacturing processes for photovoltaic devices integrated with roofing materials.

One aspect of the present invention is a photovoltaic roofing tile comprising:
a polymeric carrier tile having a top surface and a bottom surface; and
a photovoltaic element affixed to the polymeric carrier tile, the photovoltaic element having a bottom surface and a top surface having an active area.

Another aspect of the present invention is a photovoltaic roofing tile comprising:
a polymeric carrier tile having a top surface and a bottom surface; and
a photovoltaic element affixed to the polymeric carrier tile, the photovoltaic element having a bottom surface and a top surface having an active area, the bottom surface of the photovoltaic element being affixed to the top surface of the polymeric carrier tile,
wherein the polymeric carrier tile has an indentation formed in its top surface, wherein the photovoltaic element is disposed in the indentation, and wherein the lateral gap between each edge of the indentation and an edge of the photovoltaic element is less than 100 μm.

Another aspect of the present invention is a photovoltaic roofing tile comprising:
a polymeric carrier tile having a top surface and a bottom surface and an opening formed therein; and
a photovoltaic element affixed to the polymeric carrier tile, the photovoltaic element having a bottom surface and a top surface having an inactive area which is affixed to the bottom surface of the polymeric carrier tile, and an active area which is substantially aligned with the opening formed in the polymeric carrier tile.

Another aspect of the present invention is a photovoltaic roofing tile comprising:
a polymeric overlay having a top surface and a bottom surface and an opening formed therein;
a polymeric carrier tile having a top surface and a bottom surface; and
a photovoltaic element affixed to the polymeric carrier tile, the photovoltaic element having a bottom surface which is affixed to the top surface of the polymeric carrier tile, a top surface having an inactive area which is affixed to the bottom surface of the polymeric overlay, and an active area which is substantially aligned with the opening formed in the polymeric overlay.

Another aspect of the present invention is method of making a photovoltaic roofing tile comprising:
a polymeric carrier tile having a top surface and a bottom surface; and
a photovoltaic element having a top surface and a bottom surface, the top surface having an active area, the photovoltaic element being affixed to the polymeric carrier tile,

the method comprising:
inserting into a compression mold
   a polymeric tile preform having a top surface and a bottom surface, and
   the photovoltaic element, a surface of the photovoltaic element being disposed adjacent to a surface of the polymeric tile preform;
compression molding the polymeric tile preform and the photovoltaic element together to form an unfinished photovoltaic roofing tile; and
finishing the unfinished photovoltaic roofing tile to provide the photovoltaic roofing tile.

Another aspect of the present invention is a method of making a photovoltaic roofing tile
a polymeric carrier tile having a top surface and a bottom surface, one of the surfaces having an indentation formed therein; and
a photovoltaic element having a top surface and a bottom surface, the top surface having an active area, the photovoltaic element being affixed to the polymeric carrier tile and disposed in the indentation therein,
   the method comprising:
inserting into a compression mold a polymeric tile preform having a top surface and a bottom surface;
compression molding the polymeric tile preform to form a polymeric carrier tile having the indentation disposed in one of the surfaces;
disposing the photovoltaic element in the indentation; and
affixing the photovoltaic element to the polymeric carrier tile to provide the photovoltaic roofing tile.

Another aspect of the present invention is a photovoltaic device comprising a photovoltaic element having a substrate and a top surface; and a cover element substantially covering the photovoltaic element and affixed to the top surface of the photovoltaic element, wherein the cover element is longer and/or wider than the substrate of the photovoltaic element by at least 1 mm.

The accompanying drawings are not necessarily to scale, and sizes of various elements can be distorted for clarity.

### BRIEF DESCRIPTION OF THE DRAWINGS

FIG. 1. is a schematic top perspective view of a photovoltaic roofing tile according to one embodiment of the invention;

FIG. 2 is a schematic cross-sectional view of the photovoltaic roofing tile of FIG. 1;

FIG. 3 is a schematic cross-sectional view of a photovoltaic roofing tile according to another embodiment of the invention;

FIG. 4 is a schematic cross-sectional view of a photovoltaic roofing tile according to another embodiment of the invention;

FIG. 5 is a top perspective view of a photovoltaic roofing tile according to another embodiment of the invention;

FIG. 6 is a schematic cross-sectional view of a polymeric carrier tile according to one embodiment of the invention;

FIG. 7 is schematic cross-sectional view of a photovoltaic roofing tile according to another embodiment of the invention;

FIG. 8 is schematic cross-sectional view of a photovoltaic roofing tile according to another embodiment of the invention;

FIG. 9 is schematic cross-sectional view of a photovoltaic roofing tile according to another embodiment of the invention;

FIG. 10 is schematic cross-sectional view of a photovoltaic roofing tile according to another embodiment of the invention;

FIG. 11 is a vertical, sectional view of a process and apparatus for extruding a polymeric material and serially severing the extrudate into a plurality of polymeric tile preforms for delivery to a compression molding station, with the delivery mechanism being fragmentally illustrated at the right end thereof;

FIG. 12 is a top plan view of the process and apparatus shown in FIG. 11;

FIG. 13 is an illustration similar to that of FIG. 11, but in which the extruding operation includes both core material and capstock material being co-extruded prior to the serial severing step, with the delivery mechanism being fragmentally illustrated at the right end thereof;

FIG. 14 is a top plan view of one embodiment of the process and apparatus shown in FIG. 13, in which the capstock material covers a portion of the top surface of the polymeric carrier tile;

FIG. 15 is a schematic vertical elevational view of a compression molding station adapted to receive preliminary polymeric tile preform shapes delivered from the right-most end of the apparatus shown in FIG. 11 or 13, for compression molding the polymer carrier tiles together with the photovoltaic elements to form unfinished photovoltaic roofing tiles;

FIG. 16 is a top view of the compression molding station of FIG. 15, taken generally along the line VI-VI of FIG. 15, and with an indexable mold handling table shown at the right end thereof, with a robot and robot arm being schematically illustrated for removal of photovoltaic roofing tiles from molds carried by the indexable table;

FIG. 17 is a schematic elevational view of upper and lower mold components shown in the open position, at one of the stations on the indexable table, with the indexable table fragmentally illustrated, and with a robot arm for lifting the photovoltaic roofing tile from the mold;

FIG. 18 is an enlarged generally plan view of an upper mold component, taken generally along the line of VIII-VIII of FIG. 15;

FIG. 19 is an enlarged generally plan view of a lower mold component, taken generally along the line of IX-IX of FIG. 15;

FIG. 20 is an enlarged vertical sectional view, taken through the upper and lower mold components, generally along the line X-X of FIGS. 17-19;

FIG. 21 is a schematic side elevational view of another apparatus suitable for use in the present invention;

FIG. 22 is a schematic side elevational view of a preheater for preheating carrier plates being delivered along a conveyor, for return to an extruder at the left end of FIG. 21, for receiving extruded polymeric tile preforms thereon, with a portion of the preheater being broken away to illustrate a heating element therein;

FIG. 23 is a view somewhat similar to that of FIG. 22, but of an alternative embodiment of a preheater;

FIG. 24 is a top view of a carrier plate for receiving extruded polymeric tile preform material thereon for carrying the polymeric tile preform material to and during a compression molding of the polymeric tile preform material into a polymeric carrier tile;

FIG. 25 is a side elevational view of the carrier plate of FIG. 24, with portions broken away and illustrated in section, to illustrate positioning holes for receiving positioning pins therein for aligning each carrier plate in a compression mold;

FIG. 26 is a side perspective view of the return conveyor and preheater of FIG. 22 with the right portion of the return conveyor being shown broken away;

FIG. 27 is a side perspective view of the extruder for extruding polymeric tile preform-forming material and applying the same onto carrier plates that are delivered along a conveyor, fragmentally illustrating a portion of the left end of FIG. 21;

FIG. 28 is a schematic side elevational view of the two single screw extruders of FIGS. 21 and 27;

FIG. 29 is an enlarged fragmentary schematic illustration of the mechanism for severing polymeric tile preform material being extruded onto carrier plates, and a mechanism for thereafter separating the individual carrier plates with polymeric tile preform material thereon, from each other.

FIG. 30 is an enlarged fragmentary schematic illustration of a mechanism of the walking beam type for receiving carrier plates with polymeric tile preform material thereon and delivering them to a compression mold;

FIG. 31 is an enlarged fragmentary schematic illustration of a portion of the walking beam mechanism of FIG. 21 taken from the opposite side of the illustration of FIG. 21 for receiving carrier plates with polymeric carrier tiles (optionally in the form of photovoltaic roofing tiles) thereon that are received from the compression mold and with hold-downs being illustrated for the movement with the carrier plates via the walking beam, and with the carrier plates with polymeric carrier tiles thereon having flashing shown along edges thereof, and with the downward discharge of the carrier plates to the return conveyor of FIG. 22;

FIG. 32 is an enlarged fragmentary schematic illustration of the cutting mechanism for simultaneously cutting flashing from the molded polymeric carrier tiles (optionally in the form of photovoltaic roofing tiles) that are situated on secondary plates in the cutting mechanism;

FIG. 33 is a fragmentary schematic view of a cooling tower for receiving a plurality of polymeric carrier tiles (optionally in the form of photovoltaic roofing tiles) therein at a station in which the polymeric carrier tiles are loaded into a polymeric carrier tile retention mechanism for applying curvature thereto, and wherein the polymeric carrier tiles in the mechanism are then delivered up one (left) portion of the cooling tower, and down another (right) portion of the cooling tower, back to the loading station, from which they are unloaded, with a portion of one of the tower portions being broken away for clarity;

FIG. 34 is a schematic perspective rear view of the polymeric carrier tile cooling tower partially illustrated in FIG. 30, taken from the opposite side illustrated in FIG. 21;

FIG. 35 is a perspective view of one form of a lower component of the retention mechanism, adapted to receive a polymeric carrier tile therein, on its curved upper surface, and with the cooling grooves being shown in that lower component of the retention mechanism;

FIG. 36 is a longitudinal sectional view, taken through the lower component of the polymeric carrier tile retention member illustrated in FIG. 35, generally along the line 12A-12A of FIG. 35;

FIG. 37 is a longitudinal sectional view taken though an upper component of the polymeric carrier tile retention mechanism, and wherein the opposing faces of the lower and upper components 12A,12B of the retention mechanism are illustrated as being respectively concave and convex, for applying a curvature to polymeric carrier tiles sandwiched therebetween;

FIGS. 38 and 39 are end views of the polymeric carrier tile retention components of FIGS. 36 and 37 respectively;

FIG. 40 is a schematic top perspective view of an alternative embodiment of an arcuately configured lower polymeric carrier tile retention component;

FIG. 41 is a sectional view of the lower polymeric carrier tile component of FIG. 40, taken generally along the line 13A-13A of FIG. 40;

FIG. 42 is a schematic top perspective view of another embodiment of a lower polymeric carrier tile retention component, having a fan type cooling mechanism disposed for blowing cooling fluid through grooves of the component of FIG. 42;

FIG. 43 is a schematic top perspective view similar to that of FIG. 42, but wherein the fan device for cooling is provided with a refrigerant or like cooling device for cooling ambient air for the fan type cooling mechanism;

FIG. 44 is a schematic top perspective view of yet another alternative embodiment of a lower polymeric carrier tile retention component in which a coolant other than ambient air is used to cool polymeric carrier tiles via grooves therein;

FIG. 45 is a schematic side elevational view of a polymeric carrier tile that is disposed on a secondary plate, following the cutting or flashing trimming operation of FIG. 32;

FIG. 46 is a side elevation view of a polymeric carrier tile shown disposed between upper and lower retention components, after cooling of the polymeric carrier tile, while it is still disposed between the upper and lower retention components, just prior to it being removed from the unloading station illustrated in FIG. 34;

FIG. 47 is a side elevational view of a polymeric carrier tile being applied to a roof, prior to fastening the same against the roof, showing the curvature that has been applied to the polymeric carrier tile in the retention mechanism, with the roof being fragmentally illustrated;

FIG. 48 is a view taken of the polymeric carrier tile and a fragmentary portion of a roof as shown in FIG. 47, but along the line generally shown as 19A-19A of FIG. 19;

FIG. 49 is an illustration similar to that of FIG. 47, but wherein the polymeric carrier tile is shown being fastened down tightly against the roof by a fastener;

FIG. 50 is a graph showing the relative spectral response of three commonly-used photovoltaic materials as well as the spectral distribution of solar radiation; and

FIG. 51 is a schematic cross-sectional view of a photovoltaic device according to one embodiment of the invention.

FIG. 52 is an exploded layer of a photovoltaic element having a laminate structure;

FIG. 53 is a photograph showing the photovoltaic roofing tile made in Example 1;

FIG. 54 is a photograph showing a photovoltaic element being placed in an indentation in a polymeric carrier tile in Example 2; and

FIG. 55 is a photograph of a photovoltaic roofing tile made in Example 2, both before and after affixation of the photovoltaic element to the polymeric carrier tile.

### DETAILED DESCRIPTION OF THE INVENTION

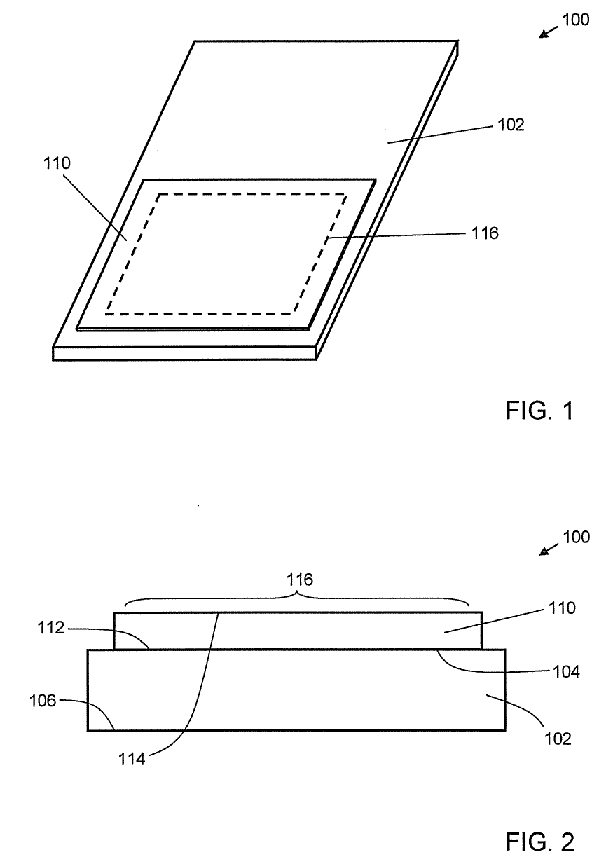

One aspect of the invention is a photovoltaic roofing tile. An example of a photovoltaic roofing tile according to this aspect of the invention is shown in schematic top perspective view in FIG. 1, and in schematic cross-sectional view in FIG. 2. Photovoltaic roofing tile 100 includes a polymeric carrier tile 102 having a top surface 104 and a bottom surface 106. Affixed to the polymeric carrier tile is a photovoltaic element 110, which has a bottom surface 112 and a top surface 114.

Photovoltaic element 110 includes one or more photovoltaic cells that can be individually electrically connected so as to operate as a single unit. Photovoltaic element 110 can be based on any desirable photovoltaic material system, such as monocrystalline silicon; polycrystalline silicon; amorphous silicon; III-V materials such as indium gallium nitride; II-VI materials such as cadmium telluride; and more complex chalcogenides (group VI) and pnicogenides (group V) such as copper indium diselenide. For example, one type of suitable photovoltaic element includes an n-type silicon layer (doped with an electron donor such as phosphorus) oriented toward incident solar radiation on top of a p-type silicon layer (doped with an electron acceptor, such as boron), sandwiched between a pair of electrically-conductive electrode layers. Photovoltaic element 110 can also include structural elements such as a substrate such as an ETFE or polyester backing; a glass plate; or an asphalt non-woven glass reinforced laminate such as those used in the manufacture of asphalt roofing shingles; one or more protectant or encapsulant materials such as EVA; one or more covering materials such as glass or plastic; mounting structures such as clips, openings, or tabs; and one or more optionally connectorized electrical leads. Thin film photovoltaic materials and flexible photovoltaic materials can be used in the construction of photovoltaic elements for use in the present invention. In one embodiment of the invention, the photovoltaic element is a monocrystalline silicon photovoltaic element or a polycrystalline silicon photovoltaic element.

Photovoltaic element 110 can include at least one antireflection coating, disposed on, for example, the very top surface of the photoelectric element or between individual protectant, encapsulant or cover elements.

Suitable photovoltaic elements can be obtained, for example, from China Electric Equipment Group of Nanjing, China and Fuji Electric System of Tokyo, Japan as well as from several domestic suppliers such as Uni-Solar, Sharp, Shell Solar, BP Solar, USFC, FirstSolar, General Electric, Schott Solar, Evergreen Solar and Global Solar.

Top surface 114 of photovoltaic element 110 is the face presenting the photoelectrically-active areas of its one or more photoelectric cells. The top surface can be the top surface of the one or more photovoltaic cells themselves, or alternatively can be the top surface of a series of one or more protectant, encapsulant and/or covering materials disposed thereon. During use of the photovoltaic roofing tile 100, top surface 114 should be oriented so that it is illuminated by solar radiation. The top surface has on it an active area 116, which is the area over which radiation striking the active face will be received by the photovoltaic cell(s) of the photovoltaic element 110.

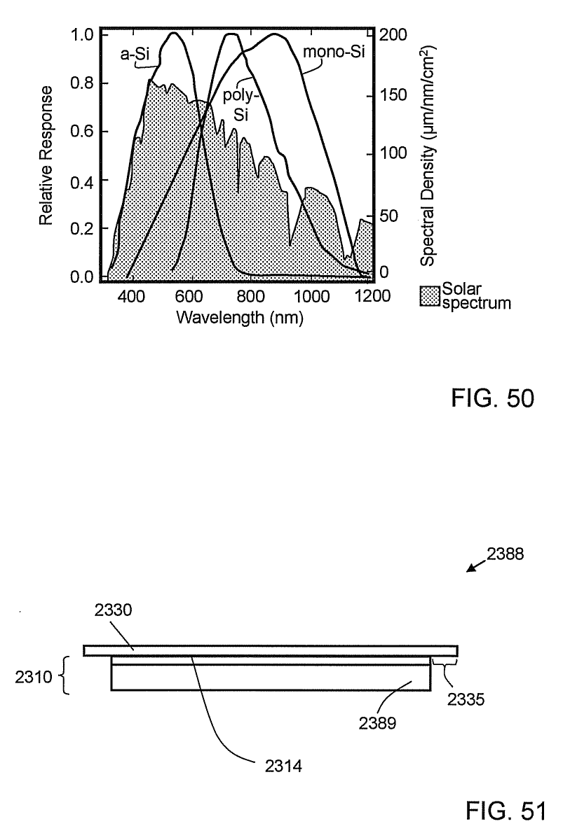

The photovoltaic element 110 also has an operating wavelength range. Solar radiation includes light of wavelengths spanning the near UV, the visible, and the near infrared spectra. As used herein, when the term “solar radiation” is used without further elaboration, it is meant to span the wavelength range of 300 nm to 1500 nm. Different photovoltaic elements have different power generation efficiencies with respect to different parts of the solar spectrum. FIG. 50 is a graph showing the relative spectral response of three commonly-used photovoltaic materials as well as the spectral distribution of solar radiation. Amorphous doped silicon is most efficient at visible wavelengths, and polycrystalline doped silicon and monocrystalline doped silicon are most efficient at near-infrared wavelengths. As used herein, the operating wavelength range of a photovoltaic element is the wavelength range over which the relative spectral response is at least 10% of the maximal spectral response. According to certain embodiments of the invention, the operating wavelength range of the photovoltaic element falls within the range of about 300 nm to about 2000 nm. Preferably, the operating wavelength range of the photovoltaic element falls within the range of about 300 nm to about 1200 nm. For example, for photovoltaic devices having photovoltaic cells based on typical amorphous silicon materials the operating wavelength range is between about 375 nm and about 775 nm; for typical polycrystalline silicon materials the operating wavelength range is between about 600 nm and about 1050 nm; and for typical monocrystalline silicon materials the operating wavelength range is between about 425 nm and about 1175 nm.

According to one embodiment of the invention, the bottom surface of the photovoltaic element is affixed to the top surface of the polymeric carrier tile. For example, in the photovoltaic roofing tile 100 shown in FIGS. 1 and 2, the bottom surface 112 of the photovoltaic element 110 is affixed to the top surface 104 of the polymeric carrier tile.

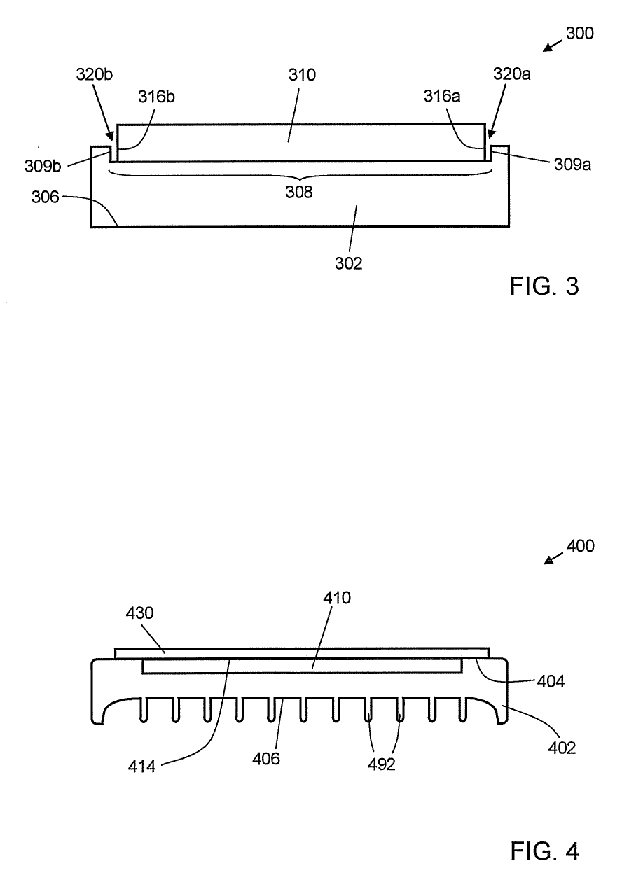

According to one embodiment of the invention, the polymeric carrier tile has an indentation formed in its top surface, and the photovoltaic element is disposed in the indentation. For example, as shown in schematic cross-sectional view in FIG. 3, the polymeric carrier tile 302 of photovoltaic roofing tile 300 has an indentation 308 formed in its top surface, in which the photovoltaic element 310 is disposed. In certain embodiments of the invention, the lateral gap between each edge of the indentation and an edge of the photovoltaic element is less than about 100 μm. For example, in the embodiment shown in FIG. 3, the lateral gap 320a between the edge 309a of the indentation 308 and the edge 316a of the photovoltaic element 310 is less than about 100 μm. Similarly, the lateral gap 320b between the edge 309b of the indentation 308 and the edge 316b of the photovoltaic element 310 is less than about 100 μm. In some embodiments of the invention, the lateral gap between each edge of the indentation and an edge of the photovoltaic element is less than about 50 μm, or even less than about 25 μm. In certain embodiments of the invention, each edge of the indentation is in substantial contact with an edge of the photovoltaic element.

The top surface of the photovoltaic element can be substantially flush (i.e., within about 2 mm or less, within about 1 mm or less, or even within about 0.5 mm or less) with the top surface of the polymeric carrier tile. For example, in the embodiment of the invention shown in FIG. 4, the top surface 414 of the photovoltaic element 410 is substantially flush with the top surface 404 of the polymeric carrier tile 402. Alternatively, the top surface of the photovoltaic element can protrude from the top surface of the polymeric carrier tile (e.g., as shown in FIG. 3), or even be recessed from the top surface of the polymeric carrier tile. Photovoltaic roofing tiles having a photovoltaic element disposed within an indentation formed in the top surface of a polymeric carrier tile can be made, for example, using the molding methods described below.

According to one embodiment of the invention, a photovoltaic roofing tile further includes a cover element substantially covering the photovoltaic element. In this embodiment of the invention, the cover element overlaps and is affixed to at least part of the top surface of the polymeric carrier tile. For example, as shown in FIG. 4, photovoltaic roofing tile 400 includes a cover element 430, which substantially covers photovoltaic element 410 and overlaps and is affixed to the top surface 404 of the polymeric carrier tile 402. The cover element can perform any of a number of functions in the photovoltaic roofing tiles of the present invention. For example, the cover element can provide physical protection and/or weatherproofing for the photovoltaic element. In other embodiments of the invention, the cover element can perform an aesthetic function, such as providing an apparent color or texture to the exposed face of the photovoltaic roofing tile.

According to one embodiment of the invention, the cover element has an energy transmissivity to solar radiation of at least about 50% over the operating wavelength range of the photovoltaic element. As used herein, an “energy transmissivity to solar radiation of at least about 50% over the operating wavelength range of [a] photovoltaic element” means that at least about 50% of the total energy is transmitted when solar radiation within the operating wavelength range illuminates the polymer structure; the energy transmissivity at each wavelength in the operating wavelength range need not be at least about 50%. Desirably, the cover element has at least about 75% energy transmissivity to solar radiation over the operating wavelength range of the photovoltaic element. In certain embodiments of the invention, the cover element has at least about 90% energy transmissivity to solar radiation over the operating wavelength range of the photovoltaic element. The skilled artisan will recognize that both the bulk properties and the thickness(es) of the material(s) of the cover element will influence the energy transmissivity of the cover element. In one embodiment of the invention, the cover element has a thickness from about 25 μm to about 2 mm. In certain embodiments of the invention, the cover element has a thickness from about 75 μm to about 1 mm. Cover elements are described, for example, in U.S. Provisional Patent Application Ser. No. 60/946,881, filed Jun. 21, 2008, which is hereby incorporated herein by reference in its entirety.

In one embodiment of the invention, the cover element is a polymer structure. The polymer structure can be formed from, for example, a single layer of a polymeric material, or multiple layers of polymeric materials. For example, the polymer structure can include two layers, including a structural supporting layer (e.g., a 6-7 mil (˜150-175 μm) thick PET film); and an adhesive layer formed between the structural supporting layer and the top surface of the photovoltaic element. The polymer structure may have other numbers of layers. The cover element can also be made from other materials, such as glass or glass-ceramic materials.

In some embodiments of the invention, the cover element has a substantially flat top surface. However, in other embodiments of the invention, the top surface of the cover element is not substantially flat. For example, the top surface of the cover element may have a patterned surface relief, or may have a roughened surface relief. The surface relief of the top surface of the cover element can be chosen to match, for example, the surface relief of the top surface of the polymeric carrier tile. Surface relief on the top surface of the polymer structure may be formed using standard techniques such as embossing or casting. In certain embodiments of the invention, the cover element has granules affixed to its top surface, as described in detail in U.S. patent application Ser. No. 11/742,909, filed on May 1, 2007 and entitled “Photovoltaic Devices and Photovoltaic Roofing Elements Including Granules, and Roofs Using Them,” which is hereby incorporated herein by reference in its entirety. In other embodiments of the invention, the cover element includes an electrochromic material, as described in U.S. Provisional Patent Application Ser. No. 60/946,881, which is hereby incorporated herein by reference in its entirety. In still other embodiments of the invention, the cover element includes a light-directing feature to more efficiently direct solar radiation to the active areas of the photovoltaic element, for example as described in International Patent Application Publication no. WO 2007/085721 A1, which is hereby incorporated by reference in its entirety.

According to another embodiment of the invention, the cover element is colored, but has at least about 50% energy transmissivity to radiation over the 750-1150 nm wavelength range. As used herein, an item that is “colored” is one that appears colored (including white, black or grey, but not colorless) to a human observer. The color can be monochromatic or polychromatic. According to one embodiment of the invention, the cover element includes (either at one of its surfaces or within it) a near infrared transmissive multilayer interference coating designed to reflect radiation within a desired portion of the visible spectrum. In another embodiment of the invention, the cover element includes (either at one of its surfaces or within it) one or more colorants (e.g., dyes or pigments) that absorb at least some visible radiation but substantially transmit near-infrared radiation. The color(s) and distribution of the colorants may be selected so that the photovoltaic device has an appearance that matches, harmonizes with and/or complements the top surface of the polymeric carrier tile. The pattern of colorant may be, for example, uniform, or may be mottled in appearance. Ink jet printing, lithography, or similar technologies can be used to provide the desired pattern of colorant. The cover element may include a pattern of colorant at, for example, the bottom surface of the cover element, the top surface of the cover element, or formed within the cover element. In certain embodiments of the invention, when the cover element is colored, the majority of the operating range of the photovoltaic element is not within the 400-700 nm wavelength range.

Embodiments of the present invention having colored cover elements can be used, for example, with photovoltaic elements having a substantial portion of their photovoltaic activity in the near infrared, such as those based on polycrystalline silicon and monocrystalline silicon materials. Photovoltaic devices made with colored polymer structures are described in further detail in U.S. patent application Ser. No. 11/456,200, filed on Jul. 8, 2006 and entitled “Photovoltaic Module,” (published as U.S. Patent Application Publication no. 2008/0006323), which is hereby incorporated herein by reference in its entirety.

In one embodiment of the invention, the cover element is sealed to polymeric carrier tile. In this embodiment of the invention, the cover element forms a watertight seal with the polymeric carrier tile, so that the photovoltaic element is protected from rain, snow and other environmental hazards.

As the skilled artisan will appreciate, the affixation or sealing of the cover element to the polymeric carrier tile can be achieved in many ways. For example, an adhesive material can be used to affix or seal the cover element to the polymeric carrier tile. The skilled artisan can use a two-part epoxy, a hot-melt thermoplastic, or a heat- or UV-curable material as the adhesive material. The cover element can also be affixed to the polymeric carrier tile by molding them together under conditions such that the material of the polymeric carrier tile, the affixed surface of the photovoltaic element, or both become adhesive. Other techniques, such as vacuum lamination, ultrasonic welding, laser welding, IR welding, or vibration welding, can also be used to affix and/or seal the cover element to the polymeric carrier tile.

In this aspect of the invention, the photovoltaic element is affixed to the polymeric carrier tile. This affixation can be achieved in a variety of ways. For example, an adhesive material can be used to affix the photovoltaic element to the polymeric carrier tile. In one embodiment of the invention, an adhesive material is disposed between a surface of the photovoltaic element and a surface of the polymeric carrier tile. The skilled artisan can use, for example, a two-part epoxy (or other multicomponent reactive adhesive system), a hot-melt thermoplastic, or a heat-curable material as the adhesive material. The photovoltaic element can be formed with an adhesive tie layer at its bottom surface, as described in more detail below. The photovoltaic element can also be affixed to the polymeric carrier tile by molding them together under conditions such that the material of the polymeric carrier tile, the affixed surface of the photovoltaic element, or both become adhesive or fuse or melt together. A pressure-sensitive adhesive can also be used to affix the photovoltaic element to the polymeric carrier tile. In other embodiments of the invention, for example the embodiment described above with reference to FIG. 4, a cover element formed over the indentation in the polymeric carrier tile affixes the photovoltaic element to its top surface.

One particular example of a polymeric adhesive is the cured product of a formulation comprising (e.g., consisting essentially of) an acrylated urethane oligomer (e.g., EBECRYL 270, available from UCB Chemicals) with 1 wt % initiator. Other suitable adhesive materials include ethylene-acrylic acid and ethylene-methacrylic acid copolymers, polyolefins, PET, polyamides and polyimides. Examples of suitable materials are described in U.S. Pat. Nos. 4,648,932, 5,194,113, 5,491,021 and 7,125,601, each of which is hereby incorporated herein by reference in its entirety.

The polymeric carrier tile can take many forms. For example, it can be formed from a single material, such as a thermoplastic polymer. Suitable polymeric materials for use in making the polymeric carrier tiles include, for example, Polyvinylchloride (PVC), Polyethylene (PE), Polypropylene (PP), Polybutene (PB-1), Polymethylpentene (PMP), Polyacrylates (PAC), Polyethyleneterephthalate (PET), Polybutyleneterephthalate (PBT), Polyethylenenaphthalate (PEN), Ethylene-Propylene-Diene Monomer Copolymers (EPDM), Styrene Butadiene Styrene (SBS), Styrene Isoprene Styrene (SIS), Acrylonitrile Butadiene Styrene (ABS), and Nitrile Rubber, their copolymers, binary and ternary blends of the above.

In one embodiment of the invention, the polymeric carrier tile comprises a core material with a layer of capstock material formed on the core material. The layer of capstock material desirably covers the core material in all areas that are exposed to the environment and subject to weathering during use. The core material is desirably a relatively inexpensive material, while the capstock material is desirably a polymer having a high weather resistance and desirable resistance to sunlight.

In some embodiments of the invention the polymeric carrier tile comprises a core that is made of a low molecular weight material such as polypropylene filled with 40-80% by weight of filler with suitable functional additives, encapsulated in a capstock material. Fillers for the core material can vary considerably and can include, for example, treated and untreated ashes (e.g., from incinerators of power stations), mineral fillers and their waste, pulp and paper waste materials, oil shale, reclaimed acrylic automotive paint and its waste and/or mixtures of any of these, or the like.

The capstock material can be chemically cross-linked to increase its mechanical properties and weather resistance and/or flame resistance and can contain functional additives such as pigments, UV light stabilizers and absorbers, photosensitizers, photoinitiators etc. The cross-linking may occur during or after processing of the material. Such cross-linking can be effected by methods which include, but are not limited to, thermal treatment or exposure to actinic radiation, e.g. ultraviolet radiation, electron beam radiation, gamma radiation. Chemical cross-linking can also be used. For example, in one embodiment of the invention vapor permeation is used to effect the cure or cross-linking of the capstock material, e.g., as described in U.S. Pat. No. 4,368,222, which is hereby incorporated herein by reference in its entirety.

In one embodiment of the invention, the capstock material is a thermoplastic olefin, a polyacrylate or a fluoropolymer. For example, the capstock material can be a polyolefin such as Polyethylene (PE), Polypropylene (PP), Polymethylpentene (PMP), Ethylene Acrylic Acid (EAA), Ethylene Methacrylic Acid (EMAA), Acrylonitrile Styrene Acrylate (ASA), Acrylonitrile Ethylene Styrene (AES) and Polybutene (PB-1), their copolymers, blends, and filled formulations, or another polymer having high weather resistance such as polyacrylates, polyurethanes and fluoropolymers and/or their copolymers blends and filled formulations. In one preferred embodiment of the invention, the capstock material is polypropylene. The capstock material can be stabilized for UV-light and weathering resistance by using additives and additive packages known in the art. In addition, the capstock materials can also contain various additives such as thermal and UV-light stabilizers, pigments, compatibilizers, processing aids, flame retardant additives, and other functional chemicals capable of improving processing of the materials and performance of the product. Foaming agents such as azodicarbonamide can be used to reduce the density of the capstock material. The top surface of the capstock layer can be modified or functionalized to improve adhesion between it and a photovoltaic element or adhesive layer, to aid in heat dissipation, or to provide beneficial dielectric properties. Useful methods to functionalize the top surface can include flame treatment, plasma treatment, corona treatment, ozone treatment, sodium treatment, etching, ion implantation, electron beam treatment, or a combination thereof. One can also add adhesion promoters, additives, a portion of tie layer resins, and/or a portion of the encapsulants into the capstock during processing.

The core material can be, for example, a virgin thermoplastic polymer material, elastomer or rubber including but not limited to Polyvinylchloride (PVC), Polyethylene (PE), Polypropylene (PP), Polybutene (PB-1), Polymethylpentene (PMP), Polyacrylates (PAC), Polyethyleneterephthalate (PET), Polybutyleneterephthalate (PBT), Polyethylenenaphthalate (PEN), Ethylene-Propylene-Diene Monomer Copolymers (EPDM), Styrene Butadiene Styrene (SBS), Styrene Isoprene Styrene (SIS), Acrylonitrile Butadiene Styrene (ABS), Polyurethane (PU) or Nitrile Rubber, their copolymers, binary and ternary blends of the above. In one preferred embodiment of the invention, the core material is made from polypropylene. In one embodiment of the invention, the core material is a filled polymer. For example, the core material can be a filled formulation based on the above or other thermoplastic materials and elastomers filled with mineral, organic fillers, nanofillers, reinforcing fillers or fibers as well as recycled materials of the above polymers. Recycled and highly filled thermoplastic materials and recycled rubber (for example from tires) can be used to decrease cost. The content of mineral fillers can be, for example, in the weight range from 5% to 80%. In addition, the core materials can also contain various additives such as thermal and ultraviolet (UV) light stabilizers, pigments, compatibilizers, processing aids, flame retardant additives, and other functional chemicals capable of improving processing of the materials and performance of the product. Some flame retardants known to have negative effects on weather resistance of polymers can still be effectively used in the core material, as the capstock layer can serve to protect the shingle from the effects of the weather. Chemical foaming agents such as azodicarbonamide may be used to reduce the density of the core material. Physical blowing agents, glass bubbles or expanded polymer microspheres may also be used to adjust the density of the core material.

The ratio of the thickness of the core material to the thickness of the layer of capstock material can be, for example, at least about 2:1. In certain embodiments of the invention, the ratio of the thickness of the core material to the thickness of the layer of capstock material is at least about 5:1, or even at least about 10:1.

Combining a capstock material with a core material allows an economic advantage in that a greater amount of filler may be used to make up the core, which will be of less expense than the material that comprises the capstock, without providing undesirable surface properties for the capstock, and without limiting the aesthetics of the product, because the core is, at least partially, encapsulated in an aesthetically pleasing and weatherable capstock. Additionally, the core can be comprised of a foam or microcellular foam material where reduced weight for the product is desired.

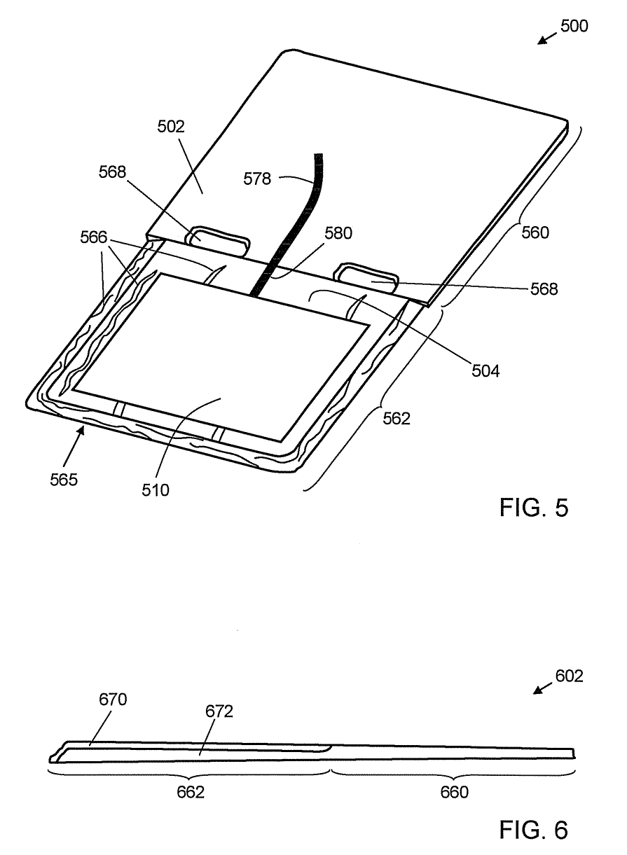

In one embodiment of the invention, the polymeric roofing tile comprises a headlap portion and a butt portion disposed lengthwise with respect to the headlap portion. The butt portion has a length in the range of, for example, 0.5-10, 0.5-5, or even 0.5-2 times the length of the headlap portion. In this embodiment of the invention, the photovoltaic element is affixed to the polymeric carrier tile in the butt portion of the polymeric roofing tile. A photovoltaic roofing tile according to this embodiment of the invention is shown in FIG. 5. The photovoltaic roofing tile 500 has a headlap portion 560 and a butt portion 562. The photovoltaic element 510 is affixed to the polymeric carrier tile 502 in the butt portion 562 of the roofing tile. In certain embodiments of the invention, and as shown in FIG. 5, the butt portion 562 of the polymeric carrier tile 502 has features 566 molded into its surface, in order to provide a desired appearance to the polymeric carrier tile. In the embodiment shown in FIG. 5, the polymeric carrier tile 502 has a pair of recessed nailing areas 568 formed in its headlap portion 560, for example as described in International Patent Application Publication no. WO 08/052,029, which is hereby incorporated herein by reference in its entirety. In certain embodiments of the invention, and as shown in FIG. 5, the photovoltaic element 510 has coupled to it at least one electrical lead 578. The electrical lead can be disposed in a channel 580 formed in the top surface 504 of the polymeric carrier tile 502. The U-shaped periphery along the right and left sides and lower edge of the butt portion 562 slopes downwardly from its top surface to its bottom surface, as shown at 565.

In certain embodiments of the invention, the polymeric carrier tile includes a capstock layer, described above, only in the butt region of the photovoltaic roofing tile. For example, the polymeric carrier tile 602 shown in side cross-sectional schematic view in FIG. 6 has a capstock material 670 formed on the core material 672 only in the butt portion 662, and not in the headlap portion 660. Of course, in other embodiments of the invention the capstock material can cover selected portions of, or even substantially the entire polymeric carrier tile, as described, for example, in U.S. Patent Application Publication no. 2007/0266562 and U.S. Pat. No. 7,351,462, each of which is hereby incorporated by reference in its entirety.

The polymeric carrier tile can be substantially solid, as shown in FIG. 2. In certain embodiments of the invention, the polymeric carrier tile has a hollowed out bottom surface. For example, as shown in FIG. 4, polymeric carrier tile 402 has a bottom surface 406 that is hollowed out. The bottom surface 406 has molded into it ribs 492 to provide strength. Ribs 492 can, for example (and as shown in FIG. 4), extend to be nearly (e.g., within 2 mm or even 1 mm) or substantially flush with the bottom edges of the polymeric carrier tile, as shown in International Patent Application no. PCT/US07/85900, filed Nov. 29, 2007, which is hereby incorporated herein by reference in its entirety. Suitable polymeric carrier tiles are disclosed in, for example, International Patent Application no. PCT/US07/85900, U.S. Patent Application publication US 2006/0029775 and U.S. Pat. No. 7,141,200, each of which is hereby incorporated herein by reference in its entirety.

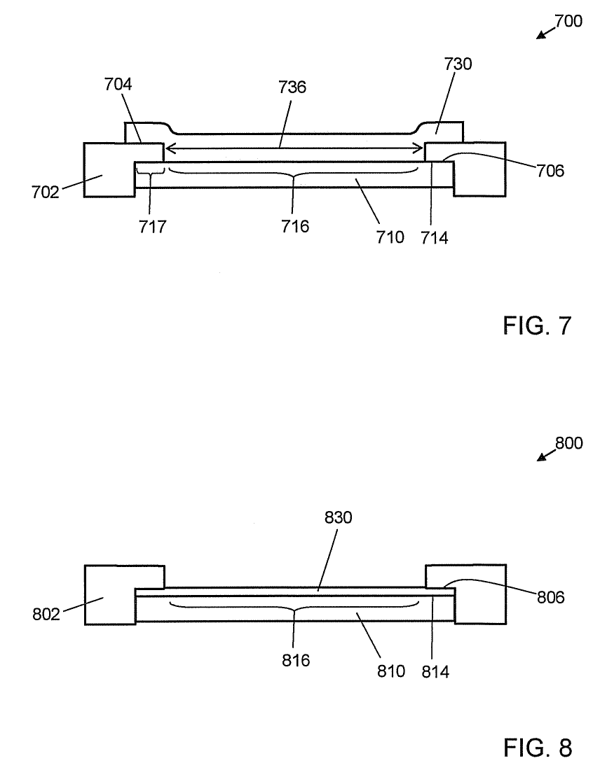

Another embodiment of the invention is shown in cross-sectional schematic view in FIG. 7. In photovoltaic roofing tile 700, polymeric carrier tile 702 has an opening 736 formed in it. The top surface 714 of the photovoltaic element 710 includes an inactive area 717, which is affixed to the bottom surface 706 of the polymeric carrier tile 702. The active area 716 of the photovoltaic element 710 is substantially aligned with the opening 736, allowing it to be illuminated by solar radiation. In certain embodiments of the invention, the inactive area can include parts of the photovoltaic element which might otherwise be photovoltaically active, but instead provide an attachment area for the polymeric carrier tile. In this embodiment of the invention, the polymeric carrier tile can hide from view all parts of the photovoltaic element except for the active area. This embodiment of the invention can provide the overall photovoltaic roofing tile with a more aesthetically pleasing appearance and/or allow non-weather-resistant components to be protected from the elements. The polymeric carrier tile used in this embodiment of the invention can be similar to those described above with respect to FIGS. 1-6. For example, the polymeric carrier tile can include a core material and a layer of capstock material formed on the core material, and can have a hollowed-out bottom surface.

In one embodiment of the invention, the polymeric carrier tile comprises a headlap portion and a butt portion disposed lengthwise with respect to the headlap portion and having a length in the range of 0.5-2 times the length of the headlap portion, as described above with reference to FIG. 5. The opening in which the photovoltaic element is disposed is formed in the butt portion of the polymeric carrier tile. In certain embodiments of the invention, the headlap portion has an opening formed therein, the photovoltaic element includes an electrical lead, and the electrical lead runs through the opening formed in the headlap portion of the polymeric carrier tile. In such embodiments of the invention, the connection of the electrical lead to the remainder of the photovoltaic element can be hidden from view and/or protected from the environment, but the electrical lead can be connected into the photovoltaic power generation system on the top face of the photovoltaic roofing tile.

In one embodiment of the invention, the photovoltaic roofing tile also includes a cover element substantially covering the photovoltaic element. As described above, the cover element overlaps and is affixed to at least part of the top surface of the polymeric carrier tile. For example, in the embodiment of the invention shown in FIG. 7, the photovoltaic roofing tile 700 includes a cover element 730, which substantially covers the active face 716 of the photovoltaic element 710 and overlaps and is affixed to the top surface 704 of the polymeric carrier tile 702. In certain embodiments of the invention, the cover element is sealed to the top surface of the polymeric carrier tile.

In another embodiment of the invention, shown in FIG. 8, the photovoltaic roofing tile 800 includes a cover element 830 substantially covering the active face 816 of the top surface 814 of the photovoltaic element 810. The cover element 830 overlaps and is affixed to at least part of the bottom surface 806 of the polymeric carrier tile 802. In certain embodiments of the invention, the cover element is sealed to the bottom surface of the polymeric carrier tile.

According to one embodiment of the invention, and as shown in FIGS. 7 and 8, the polymeric carrier tile has an indentation formed in its bottom surface, and the photovoltaic element is disposed in the indentation. In certain embodiments of the invention, the lateral gap between each edge of the indentation and an edge of the photovoltaic element is less than about 100 μm. In some embodiments of the invention, the lateral gap between each edge of the indentation and an edge of the photovoltaic element is less than about 50 μm, or even less than about 25 μm.

As described above with respect to the embodiments of FIGS. 1-8, the photovoltaic element may be affixed to the polymeric carrier tile in any of a number of ways. For example, in one embodiment of the invention, an adhesive layer is disposed between the inactive area of the top surface of the photovoltaic element and the bottom surface of the polymeric carrier tile.

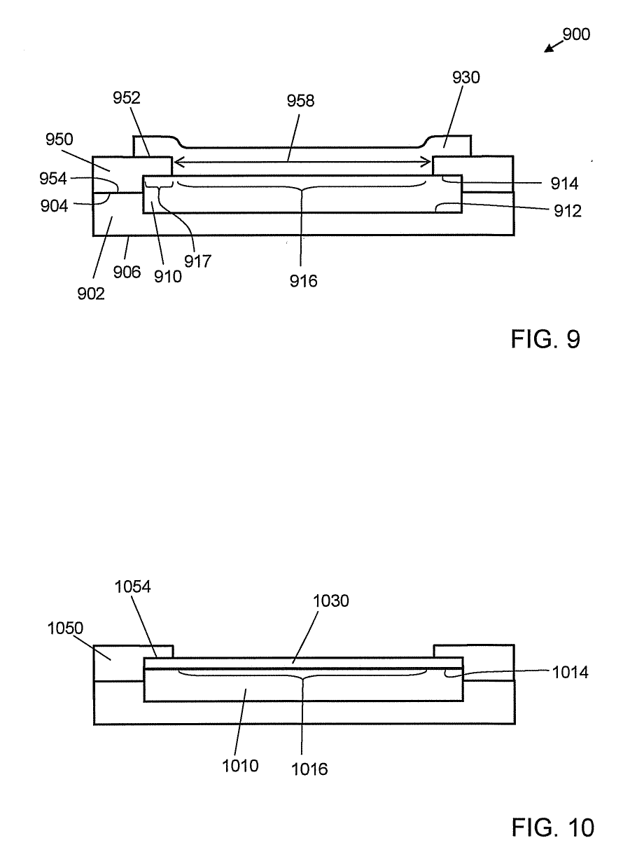

Another embodiment of the invention is shown in schematic side view in FIG. 9, In this embodiment of the invention, a photovoltaic roofing tile 900 includes a polymeric carrier tile 902 having a top surface 904 and a bottom surface 906, and a photovoltaic element 910 having a bottom surface 912 and a top surface 914. The top surface 914 of the photovoltaic element 910 has an active area 916 and an inactive area 917. The bottom surface 912 of the photovoltaic element 910 is affixed to the top surface 904 of the polymeric carrier tile 902. The photovoltaic roofing tile 900 also includes a polymeric overlay 950, having a top surface 952 and a bottom surface 954, and an opening 958 formed therein. The inactive area 917 of the top surface 914 of the photovoltaic element 910 is affixed to the bottom surface 954 of the polymeric overlay 950. The active area 916 of the top surface 914 of the photovoltaic element 910 is substantially aligned with the opening 958 formed in the polymeric overlay 950. In certain embodiments of the invention, the inactive area can include parts of the photovoltaic element which might otherwise be photovoltaically active, but instead provide an attachment area for the polymeric overlay.

As described above, the photovoltaic element may be affixed to the polymeric carrier tile in any of a number of ways. For example, in one embodiment of the invention, an adhesive layer is disposed between the inactive area of the top surface of the photovoltaic element and the bottom surface of the polymeric overlay. In another embodiment of the invention, an adhesive layer is disposed between the bottom surface of the photovoltaic element and the top surface of the polymeric carrier tile. Some embodiments of the invention have both a first adhesive layer disposed between the bottom surface of the polymeric overlay and the inactive area of the top surface of the photovoltaic element, and a second adhesive layer disposed between the bottom surface of the photovoltaic element and the top surface of the polymeric carrier tile. Of course, the photovoltaic element can also be affixed to the polymeric carrier tile and/or the polymeric overlay by molding them together under conditions such that the material of the polymeric carrier tile, the affixed surface of the photovoltaic element, or both become adhesive or fuse or melt together.

As described above, the photovoltaic roofing tiles according to this embodiment of the invention can include a cover element. For example, in the embodiment of the invention shown in FIG. 9, the photovoltaic roofing tile 900 includes a cover element 930, which substantially covers the active area 916 of the top surface 914 of the photovoltaic element 910 and overlaps the top surface 952 of the polymeric overlay 950. In certain embodiments of the invention, the cover element is sealed to the top surface of the polymeric overlay. Alternatively, as shown in FIG. 10, the cover element 1030 can substantially cover the active area 1016 of the top surface 1014 of the photovoltaic element 1010 and overlap the bottom surface 1054 of the polymeric overlay 1050. In certain embodiments of the invention, the cover element is sealed to the bottom surface of the polymeric overlay.

In embodiments of the invention having a polymeric overlay, the polymeric overlay may be integrated into the photovoltaic roofing tile in a number of ways. For example, the bottom surface of the polymeric overlay can be affixed to the top surface of the polymeric carrier tile. In the embodiment shown in FIG. 9, for example, bottom surface 954 of the polymeric overlay 950 is affixed to the top surface 904 of the polymeric carrier tile 902. The polymeric overlay and the polymeric carrier tile can be affixed to one another using an adhesive layer. In certain embodiments of the invention, the polymeric overlay and the polymeric carrier tile are affixed to one another by being molded together under conditions such that the material of the polymeric carrier tile, the material of the polymeric overlay, or both become adhesive or fuse or melt together. In some embodiments of the invention, the polymeric carrier tile is not affixed to the polymeric overlay; instead, the photovoltaic roofing tile is held together by the photovoltaic element being affixed to both the polymeric carrier tile and the polymeric overlay. In one embodiment of the invention, the photovoltaic element includes an electrical lead, which is at least partially disposed between the polymeric overlay and the polymeric carrier tile.

In one embodiment of the invention, the polymeric overlay substantially covers the polymeric carrier tile. In other embodiments of the invention, the polymeric overlay does not substantially cover the polymeric carrier tile. For example, when the photovoltaic roofing tile includes a headlap portion and a butt portion as described above with reference to FIGS. 5 and 6, the polymeric overlay can be disposed in the butt portion of the photovoltaic roofing tile, but not in the headlap portion.

As described above with reference to FIG. 7 for the polymeric carrier tile, and as shown in FIG. 9, the bottom surface of the polymeric overlay can have an indentation formed in it, with the photovoltaic element being disposed in the indentation. For example, in the embodiment shown in FIG. 9, the bottom surface 954 of polymeric overlay 950 has an indentation formed in it, in which the top surface 914 of the photovoltaic element 910 is disposed. In certain embodiments of the invention, the lateral gap between each edge of the indentation of the polymeric overlay and an edge of the photovoltaic element is less than about 100 μm. In some embodiments of the invention, the lateral gap between each edge of the indentation of the polymeric overlay and an edge of the photovoltaic element is less than about 50 μm, or even less than about 25 μm. Similarly, as described above with reference to FIG. 3, and as shown in FIG. 9 the polymeric carrier tile can have an indentation formed in it, with the photovoltaic element being disposed in it. For example, in the embodiment shown in FIG. 9, polymeric carrier tile 902 has an indentation formed in its top surface 904, in which the bottom surface 912 of the photovoltaic element 910 is disposed. In certain embodiments of the invention, the lateral gap between each edge of the indentation of the polymeric carrier tile and an edge of the photovoltaic element is less than about 100 μm. In some embodiments of the invention, the lateral gap between each edge of the indentation of the polymeric carrier tile and an edge of the photovoltaic element is less than about 50 μm, or even less than about 25 μm. In some embodiments of the invention, the top surface of the photovoltaic element is disposed in an indentation formed in the bottom surface of the polymeric overlay, and the bottom surface of the photovoltaic element is disposed in an indentation formed in the top surface of the polymeric carrier tile.

The photovoltaic roofing tiles described above are generally installed as arrays of photovoltaic roofing tiles. Accordingly, another aspect of the invention is an array of photovoltaic roofing tiles as described above. The array can include any desirable number of photovoltaic roofing tiles, which can be arranged in any desirable fashion. For example, the array can be arranged as partially overlapping, offset rows of photovoltaic roofing tiles, in a manner similar to the conventional arrangement of roofing materials. The photovoltaic roofing tiles within the array can be electrically interconnected in series, in parallel, or in series-parallel.

One or more of the photovoltaic roofing tiles described above can be installed on a roof as part of a photovoltaic system for the generation of electric power. Accordingly, one embodiment of the invention is a roof comprising one or more photovoltaic roofing tiles as described above disposed on a roof deck. The photovoltaic elements of the photovoltaic roofing tiles can be connected to an electrical system, either in series, in parallel, or in series-parallel. There can be one or more layers of material, such as underlayment, between the roof deck and the photovoltaic roofing tiles of the present invention. The photovoltaic roofing tiles of the present invention can be installed on top of an existing roof, in such embodiments, there would be one or more layers of standard (i.e., non-photovoltaic) roofing elements (e.g., asphalt coated shingles) between the roof deck and the photovoltaic roofing tiles of the present invention. Electrical connections can be, for example, made using cables, connectors and methods that meet UNDERWRITERS LABORATORIES and NATIONAL ELECTRICAL CODE standards. Electrical interconnection systems suitable for use with the photovoltaic roofing tiles of the present invention include those described in U.S. patent application Ser. No. 11/743,073, entitled “Photovoltaic Roofing Wiring Array, Photovoltaic Roofing Wiring System and Roofs Using Them,” which is hereby incorporated herein by reference in its entirety. The roof can also include one or more standard roofing elements, for example to provide weather protection at the edges of the roof, or in any hips, valleys, and ridges of the roof. In some embodiments of the invention, standard roofing elements are distributed or interspersed throughout the roof to provide an aesthetic effect, for example as described in U.S. patent application Ser. No. 11/412,160, filed on Apr. 26, 2006 and entitled “Shingle with Photovoltaic Element(s) and Array of Same Laid Up on a Roof” (published as U.S. Patent Application Publication 2007/0251571), which is hereby incorporated herein by reference in its entirety.

Another aspect of the invention is a method of making a photovoltaic roofing tile. A polymeric tile preform having a top surface and a bottom surface is inserted into a compression mold. Also inserted into the compression mold is a photovoltaic element having a bottom surface and a top surface, which has an active area. A surface (either the top surface or the bottom surface) of the photovoltaic element is disposed adjacent to a surface of the polymeric tile preform. For example, the bottom surface of the photovoltaic element can be disposed adjacent to the top surface of the polymeric tile preform. After the photovoltaic element and the polymeric tile preform are inserted into the compression mold, they are compression molded together to form an unfinished photovoltaic roofing tile. The unfinished photovoltaic roofing tile is finished to provide a photovoltaic roofing tile, which has a polymeric carrier tile having a top surface and a bottom surface; and affixed to the carrier tile a photovoltaic element having a top surface and a bottom surface. The top surface of the photovoltaic element has an active area.

Finishing the unfinished photovoltaic roofing tile can take many forms. For example, finishing the unfinished photovoltaic roofing tile can comprise (in any order) removing the unfinished photovoltaic roofing tile from the compression mold and allowing the unfinished photovoltaic roofing tile to cool. In many cases, the compression molding process will create flashing (i.e., excess polymeric material along one or more edges of the unfinished photovoltaic roofing tile). Accordingly, in some embodiments of the invention, finishing the unfinished photovoltaic roofing tile comprises removing flashing from the edges of the unfinished photovoltaic roofing tile. To provide a photovoltaic roofing tile having a desired shape, it may be desirable in some embodiments of the invention to apply a curvature to the polymeric carrier tile. In some embodiments of the invention, electrical leads and/or connectors are included with the photovoltaic element during the molding step. They can be partially or completely molded into the polymeric carrier tile (e.g., as shown in FIG. 5) or can remain free from the polymeric carrier tile. However, in some embodiments of the invention, the photovoltaic element is supplied to the compression mold without an electrical lead and/or connector. Accordingly, in some embodiments of the invention, finishing the unfinished photovoltaic roofing tile comprises coupling an electrical lead and/or connector to the photovoltaic element, so that it may be connected into an electrical interconnection system.

The compression molding methods according to this aspect of the invention can be used to produce photovoltaic roofing tiles in any of the configurations described above. For example, in order to produce a photovoltaic roofing tile in which the bottom surface of the photovoltaic element is affixed to the top surface of the polymeric carrier tile, as shown in FIGS. 1 and 3, the photovoltaic element can be inserted into the compression mold so that its bottom surface is disposed adjacent to the top surface of the polymeric tile preform. During compression molding, the bottom surface of the photovoltaic element is affixed to the top surface of the polymeric carrier tile.

Alternatively, to produce a photovoltaic roofing tile in which the top surface of the photovoltaic element is affixed to the bottom surface of the polymeric carrier tile, as shown in FIG. 7, the photovoltaic element can be inserted into the compression mold so that an inactive area on its top surface is disposed adjacent to the bottom surface of the polymeric tile preform, and the active area on its top surface is substantially aligned with an opening formed in the polymeric preform. During compression molding, the inactive area of the top surface of the photovoltaic element is affixed to the bottom surface of the polymeric element.

The compression molding methods according to this aspect of the invention can also be used to produce a photovoltaic roofing tile in which the bottom surface of the photovoltaic element is affixed to the top surface of the polymer carrier tile, and the top surface of the photovoltaic element is affixed to the bottom surface of a polymeric overlay, as shown in FIG. 9. To produce such a photovoltaic roofing tile, the photovoltaic element is inserted into the compression mold so that an inactive area of its top surface is disposed adjacent to the bottom surface of a polymeric overlay preform, which has an opening formed therein; and its bottom surface is disposed adjacent to the top surface of the polymeric tile preform. During the compression molding, the inactive area of the top surface of the photovoltaic element is affixed the bottom surface of the polymeric overlay, and the bottom surface of the photovoltaic element is affixed to the top surface of the polymeric carrier tile.

The compression molding methods according to this aspect of the invention can be used to produce photovoltaic roofing tiles in which the photovoltaic element is disposed in an indentation formed in the polymeric carrier tile or in a polymeric overlay. In certain desirable embodiments of the invention, the compression molding step at least partially embeds the photovoltaic element into a surface of the polymeric carrier tile or the polymer overlay, thereby creating an indentation. The compression molding can be performed in a manner such that there is very little lateral gap (e.g., less than about 100 μm, less than about 50 μm, or even less than about 25 μm) between each edge of the indentation and an edge of the photovoltaic element. The compression molding step can, for example, leave each edge of the indentation in substantial contact with an edge of the photovoltaic element. The compression molding step can also leave the top surface of the photovoltaic element substantially flush with the surface of the polymeric carrier tile, as described hereinabove.

In some embodiments of the invention, the surface of the polymeric tile preform adjacent to which the photovoltaic element is disposed is in a softened (e.g., at least partially molten) state when the photovoltaic element is disposed adjacent to it and during the compression molding step. For example, the polymer can be in a state in which it is formable without any substantial residual stresses remaining in the product after pressure has been exerted during molding.

For example, as described below, the polymeric tile preform can be formed by extrusion, and the still warm extruded preform can be used in the subsequent process steps.

As described above, the photovoltaic element can be affixed to the polymeric carrier tile (and optionally a polymeric overlay) in a variety of ways. In certain embodiments of the invention, an adhesive material is disposed between the photovoltaic element and the polymeric carrier tile. In methods used to make such embodiments of the invention, it may be desirable to insert an adhesive layer in between the photovoltaic element and the polymeric carrier tile (or polymeric overlay). For example, in methods used to make the photovoltaic roofing tiles of FIGS. 1 and 3, it may be desirable to insert an adhesive layer into the compression mold in between the bottom surface of the photovoltaic element and the top surface of the polymeric tile preform. Alternatively, the adhesive layer can be joined to the photovoltaic element and/or the polymeric carrier tile with appropriate relative positioning before insertion into the compression mold. In methods used to make the photovoltaic roofing tile of FIG. 7, it may be desirable to insert an adhesive layer into the compression mold in between the inactive area of the top surface of the photovoltaic element and the bottom surface of the polymeric tile preform. This adhesive layer is desirably disposed so that the adhesive material does not cover the active area of the photovoltaic element. For example, strips of adhesive material can be arranged against the inactive area of the top surface of the photovoltaic element, or a single sheet of adhesive material with an opening formed therein can be used. The adhesive layer can be joined to the photovoltaic element and/or the polymeric carrier tile with appropriate relative positioning before insertion into the compression mold. In methods used to make the photovoltaic roofing tile of FIG. 9, it may be desirable to insert an adhesive layer into the compression mold in between the bottom surface of the photovoltaic roofing element and the top surface of the polymeric tile preform; in between the top surface of the photovoltaic roofing element and the bottom surface of the polymeric tile preform; or both. The adhesive layer can be joined to the photovoltaic element, the polymeric overlay and/or the polymeric carrier tile with appropriate relative positioning before insertion into the compression mold.

In one embodiment of the invention, the photovoltaic element has an adhesive layer at the surface to be affixed to the polymeric carrier tile (e.g., at its bottom surface when making the photovoltaic roofing tile of FIG. 3 or FIG. 9; or at the edges of its top surface when making the photovoltaic roofing tile of FIG. 7). Under the pressure and heat of the compression molding step, the adhesive layer can melt, flow, and/or bond to the material of the polymeric tile preform. The use of an adhesive layer can help increase the durability of the photovoltaic element and maintain its power generation performance. Adhesive layers (also known as “tie layers”) are described in U.S. Provisional Patent Application 60/985,932, filed Nov. 6, 2007, and in U.S. Provisional Patent Application 60/985,935, filed Nov. 6, 2007, each of which is incorporated herein by reference in its entirety.

Examples of suitable materials for tie layers include, for example, functionalized polyolefins having acid or acid anhydride functionality such as maleic anhydride (see, e.g., U.S. Pat. No. 6,465,103, which is hereby incorporated by reference in its entirety); EVA or anhydride-modified EVA (see, e.g., U.S. Pat. No. 6,632,518, which is hereby incorporated herein by reference in its entirety); acid-modified polyolefins such as ethylene-acryclic acid copolymers and ethylene-methacrylic acid copolymers; combinations of acid-modified polyolefins with amine-functional polymers (see, e.g., U.S. Pat. No. 7,070,675, which is hereby incorporated herein by reference in its entirety); amino-substituted organosilanes (see, e.g., U.S. Pat. No. 6,573,087, which is hereby incorporated herein by reference in its entirety); maleic anhydride-grafted EPDM (see, e.g., U.S. Pat. No. 6,524,671, which is hereby incorporated herein by reference in its entirety); hot melts containing thermoplastic or elastomer fluoropolymer (see, e.g., U.S. Pat. No. 5,143,761, which is hereby incorporated herein by reference in its entirety); epoxy resins (e.g., BondiT, commercially available from Reltek LLC); and UV curable resins (see, e.g., U.S. Pat. No. 6,630,047, which is hereby incorporated herein by reference in its entirety). The tie layer system can have a multi-layer structure. For example, the tie layer can include an adhesive layer in combination with a reinforcing layer and/or a surface activation layer.

For example, in one embodiment of the invention, the tie layer is a blend of functionalized EVA and polyolefin. Such a tie layer can be especially suitable for use with a polymeric carrier tile having an upper surface formed from polyolefins such as polypropylene and polyethylene. For example, blends containing 5-50% (e.g., 15-35%) by weight of polyolefin can be suitable for use. Other particular examples of tie layers suitable for use in the present invention include HB Fuller HL2688PT (an EVA-based pressure sensitive adhesive); DuPont BYNEL E416 (maleic acid-grafted EVA); Equistar PLEXAR 6002 (maleic acid-grafted polypropylene); a blend of 70% polypropylene (Basell KS021P) and 30% EVA (BYNEL E418); a blend of polypropylene (Basell KS021P) and EVA (BYNEL E418) (e.g., in a 70/30 or a 50/50 ratio); Arkema LOTADER AX8900 (epoxy and maleic acid-grafted ethylene butyl acrylate); a blend of polypropylene (Basell KS021P), PVDF (Arkema 2500), and HP Fuller 9917 (a functionalized EVA-based pressure sensitive adhesive) (e.g., in a 50/25/25 ratio); Dow VERSIFY DE2300 (12% polyethylene/polypropylene copolymer); HP Fuller 9917; DuPont BYNEL 3820 (EVA); a bilayer of DuPont Bynel 3860 and 70% polypropylene/30% EVA; a blend of polypropylene (Basell KS021P) and EVA (DuPont BYNEL 3860) (e.g., in a 32/68); and a blend of polypropylene (Basell KS021P) and EVA (DuPont BYNEL 3859) (e.g., in a 15/85 ratio).

Surfaces to be adhered can be treated or activated prior to application of the tie layer. For example, such methods can include the use of, for example, reducing agents (e.g., sodium naphthalide), primers such as those comprising amine-functional acrylics or amine-derived functionalities, corona treatment, flame treatment, gas-reactive plasma, atmospheric plasma activation, cleaning with solvent, or plasma cleaning.

The tie layers can be continuous, or in other embodiments can be discontinous. In some embodiments of the invention, the tie layer underlies the entire area of the photovoltaic element. Alternatively, tie layer material can be configured in various manners at the bottom of the photovoltaic element, for example, as spots, stripes or lattices. Tie layer material can also be selectively located around the perimeter of the bottom side of the photovoltaic element.

The photovoltaic element can have a laminate structure. For example, in one embodiment of the invention, the photovoltaic element is provided as a laminate having an upper transparent encapsulant layer, a layer of photovoltaic devices, and a lower tie layer (to be used in affixing the photovoltaic element to a polymeric tile preform), with adhesive layers in between the upper layer and the photovoltaic layer; and in between the photovoltaic layer and the lower layer. For example, the photovoltaic element shown in exploded view in FIG. 52, has an upper film (e.g., formed from fluoropolymer based materials such as ETFE, PVDF, PVF, FEP, PFA, PCTFE or FEP); an adhesive encapsulant layer (e.g., formed from EVA, polyurethane, or silicone); a layer of photovoltaic devices (e.g., photovoltaic cells such as T-Cells available from Uni-Solar); a second adhesive encapsulant layer; and a tie layer. Other laminate structures can be used in the present invention. For example, in certain embodiments of the invention, the photovoltaic element is provided as a transparent encapsulant layer laminated to a photovoltaic layer. Moreover, a protective layer (e.g., formed from the fluoropolymers described above) can be provided between the photovoltaic devices and the tie layer.

A vacuum lamination process can be used to form a photovoltaic element having a laminate structure. Such a process can remove unwanted air bubbles between the surface of the upper transparent encapsulant layer and the photovoltaic layer, and to cause the EVA used as an adhesive encapsulant to melt, flow and cure. The vacuum lamination process typically takes 10-30 minutes per cycle, depending on the chemistry of the EVA and the masses of the layers and the vacuum lamination apparatus structures. In certain embodiments of the invention, vacuum lamination is used to form an upper transparent encapsulant layer on a photovoltaic layer, to which a tie layer can be added in a subsequent step.

In other embodiments of the invention, the compression molding step is performed under vacuum. For example, the compression molding step can be performed in a vacuum enclosure. The laminate layers and the polymeric tile preform can be arranged in the compression mold. Heat and vacuum can then be applied, after which molding pressure can be applied to laminate the layers to the polymeric tile preform as well as shape the polymeric tile preform to form the polymeric carrier tile. After molding, gas (e.g., air) can be allowed to enter the vacuum enclosure, the enclosure can be opened, and the photovoltaic roofing tile can be removed from the mold and enclosure. Vacuum compression molding as described below can also be used to affix a cover element to the photovoltaic roofing tile.

Another aspect of the invention is a method for making a photovoltaic roofing tile. The photovoltaic roofing tile comprises a polymeric carrier tile having a top surface and a bottom surface, one of which has an indentation formed therein. The photovoltaic roofing tile also comprises a photovoltaic element having a top surface and a bottom surface, the photovoltaic element being affixed to the polymeric carrier tile and disposed in the indentation therein. The method comprises inserting into a compression mold a polymeric tile preform having a top surface and a bottom surface; compression molding the polymeric tile perform to form a polymeric carrier tile having the indentation formed in one of the surfaces; disposing the photovoltaic element in the indentation; and affixing the photovoltaic element to the polymeric carrier tile to provide the photovoltaic roofing tile. In certain embodiments of the invention, the difference in lateral dimensions (i.e., in the plane of the photovoltaic element) between the photovoltaic element and the indentation are less than about 1 mm, less than about 500 μm, or even 100 μm.

The polymeric tile preform can be provided as described above. The compression molding can be performed substantially as provided above, but using a molding element to provide the desired indentation in the appropriate surface of the polymeric carrier tile. For example, one of the compression molds can be surfaced to form an indentation of an appropriate size and shape (e.g., a size and shape about equal to that of the photovoltaic element to be disposed in the indentation). Alternatively, a dummy insert or template of an appropriate size and shape can be placed in the compression mold along with the polymeric tile preform, and after compression molding can be removed from the surface of the molded polymeric carrier tile to leave the indentation.

The photovoltaic element can then be disposed in the indentation in the surface of the polymeric carrier tile. The photovoltaic element can, for example, have an adhesive layer at the surface to be affixed to the polymeric carrier tile, or an adhesive material can be placed between the photovoltaic element and the polymeric carrier tile. The adhesive material can, for example, be provided on the tile, on the photovoltaic element, or both, or can be provided as a separate sheet. Alternatively, a cover element can be used to affix and/or seal the photovoltaic element in the indentation, as described above. In other embodiments of the invention, vibration welding is used to fuse the photovoltaic element to the polymeric carrier tile; this method can be advantaged in that it provides very specific areas of bonding, and does not require heating large areas of the polymeric carrier tile or photovoltaic element.

As described above, photovoltaic elements having laminate structures can be used in this aspect of the invention. For example, in one embodiment of the invention, a laminate of the top four layers of the structure of FIG. 52 can be formed by vacuum lamination. An adhesive tie layer can then be affixed to the bottom of the laminate, for example by extrusion coating. The laminate photovoltaic element so formed can be placed into an indentation formed in a polymeric carrier tile, and affixed as described above. Encapsulated photovoltaic elements (see, e.g., U.S. Pat. No. 5,273,608, which is hereby incorporated herein by reference in its entirety) can also be used. Photovoltaic elements having laminate structures or encapsulated structures can also be used in the compression molding methods of the present invention.

The compression molding methods according to this aspect of the invention can be used to make the photovoltaic roofing elements including cover elements described above. Generally, a cover element preform can be inserted in the compression mold along with the photovoltaic element and the polymeric tile preform. For example, in methods used to make the photovoltaic roofing tiles of FIG. 4, a cover element can be inserted into the compression mold adjacent to the top surface of the photovoltaic element. During the compression molding step, the cover element is affixed to at least part of the top surface of the polymeric carrier tile. In methods used to make the photovoltaic roofing tile of FIG. 7, it may be desirable to insert a cover element into the compression mold adjacent to the top surface of the photovoltaic element. During the compression molding step, the cover element is affixed to at least part of the top surface of the polymeric carrier tile. In methods used to make the photovoltaic roofing tile of FIG. 8, the cover element can be inserted into the compression mold between the top surface of the photovoltaic element and the bottom surface of the polymeric tile preform. During the compression molding step, the cover element is affixed to at least part of the bottom surface of the polymeric carrier tile. In methods used to make the photovoltaic roofing tile of FIG. 9, a cover element can be inserted into the compression mold adjacent to the top surface of the photovoltaic element. During the compression molding step, the cover element is affixed to at least part of the top surface of the overlay. In methods used to make the photovoltaic roofing tile of FIG. 10, a cover element can be inserted into the compression mold between the top surface of the photovoltaic element and the bottom surface of the polymeric overlay. During the compression molding step, the cover element is affixed to at least part of the bottom surface of the polymeric overlay. Of course, other methods can be used to form cover elements on the photovoltaic roofing tiles of the present invention.

In certain methods for making photovoltaic roofing elements including cover elements as described above, the cover element is affixed to the top surface of the photovoltaic element before insertion into the compression mold with the polymeric tile preform. The cover element can be used to protect the photovoltaic element during manufacture of the photovoltaic roofing tile. The cover element can also be used in the manufacturing process to provide an area for workers or machinery to grip while transporting or working with the photovoltaic element, thereby reducing handling during manufacture. The cover element can also bear an adhesive, or have adhesive properties itself, such that it affixes the photovoltaic element to the polymeric carrier tile and/or the polymeric overlay during the compression molding.

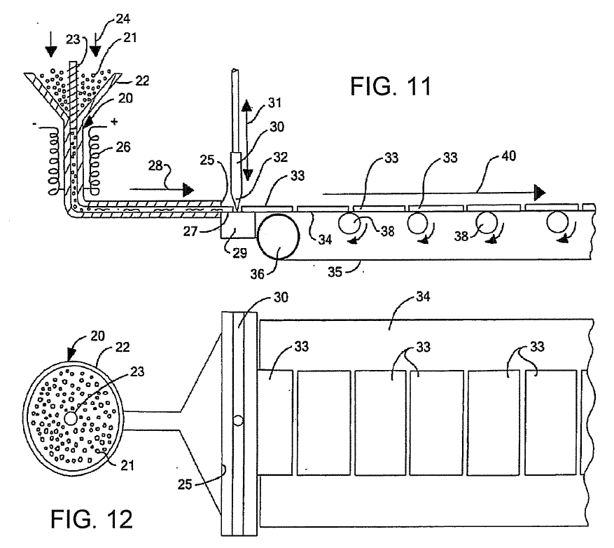

One example of a manufacturing process adaptable for performing the methods and making the photovoltaic roofing tiles of the present invention is described generally in U.S. Patent Application Publication no. 2006/0029775, and is described below with reference to FIGS. 11-20. Of course, other manufacturing processes can be used for performing the methods and making the photovoltaic roofing tiles of the present invention. In one embodiment, a polymeric tile preform is first made by extruding a cross-section that will be generally similar to the finished cross-section of the polymeric carrier tile, with the polymeric tile preform then being allowed to cool somewhat prior to placement of it in the compression mold. By first getting the polymeric tile preform to conform closely to the final polymeric carrier tile shape before placing it in the compression mold with the photovoltaic element, long flow distances and hence higher material temperatures are avoided. The material in the compression mold is then compression molded to achieve its final dimensions. In this method, very short cooling cycles can be achieved.

In another embodiment of the manufacturing process, the amount of cooling of the polymeric tile preform is minimized prior to placement in the compression mold. In this way, significant amounts of heat do not need to be provided, allowing a shortened cooling cycle to be obtained. Also, higher molecular weight polymeric materials with higher viscosities and better polymer performance properties can be used, because the shape of the polymeric tile preform is close to that of the molded polymeric carrier tile, and so the amount of material flow necessary to produce the desired finished photovoltaic roofing tile shape is minimal.

Referring now to FIGS. 11, 12 and 15, it will be seen that an extruder is generally designated by the numeral 20 for receiving generally thermoplastic pellets 21 into an inlet hopper 22 thereof, and with an auger 23 being rotatably driven, to urge the pellets through the extruder 20 in the downward direction of the arrow 24, through the extruder, to be discharged at discharge end 25. The pellets can be dried prior to adding them to the extruder. Such drying may include exposing the pellets to a drying cycle of up to 4 hours or more, at an elevated temperature (e.g., 180° F.). A suitable heater, such as electric coils 26, is provided for heating the thermoplastic material 21 in the extruder, so that it can be extruded into a desired shape as may be determined by the outlet mouth 25 of the extruder 20. The extrudate 27 is then moved horizontally in the direction of the arrow 28, beneath a transverse cutting mechanism 30 in the form of a guillotine, which is movable upwardly and downwardly in the direction of the double-headed arrow 31, with the blade 32 of the guillotine, operating against an anvil 29, to sever the extrudate 27 into a plurality of polymeric tile preforms 33. The polymeric tile preforms 33 then pass onto an upper run 34 of a continuously moving conveyor belt 35 driven between idler end roller 36 and motor-driven end roller 37, with the upper run 34 of the belt 35 being supported by suitable idler rollers 38, as the polymeric tile preforms 33 are delivered rightward, in the direction of the arrow 40 illustrated in FIG. 11. In lieu of a guillotine 30, any other type of cutting mechanism, such as for example only, a blade or other cutter movable transversely across the belt 35, or the die lip at the discharge end 25 of the extruder, in a direction perpendicular to the arrow 40 can be used to separate the extrudate into a plurality of polymeric tile preforms 33. The belt which supports the polymeric tile preforms can be a vented belt made of a suitable material, such as, for example, a silicone coated belt, or a metal mesh belt, or the like, in order to control bubbling or outgassing of gasses from the extrudate, if desired.

In the embodiment of FIGS. 11 and 12, the polymeric tile preforms 33 are extruded into a single layer of material from the shingle extruder 20.

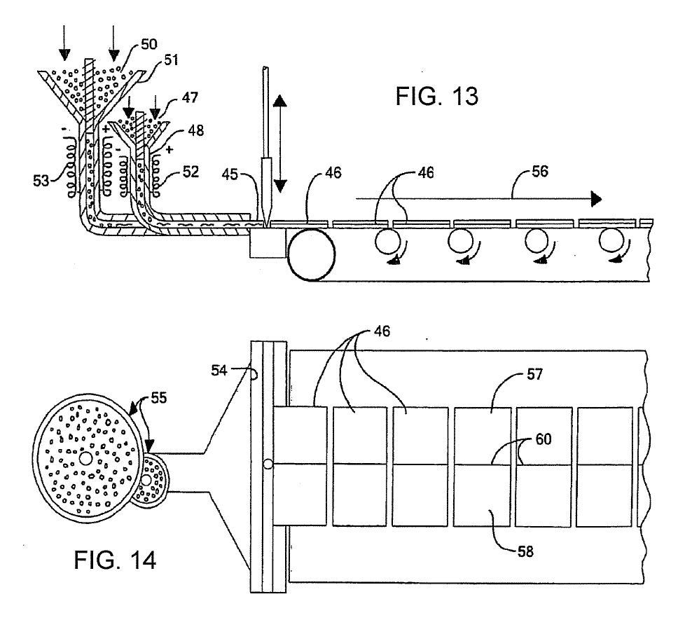

With reference now to FIGS. 13 and 14, it will be seen that some embodiments of the manufacturing process can use a co-extrusion process, in which a capstock or skin material 47 is extruded through extruder 48, while a core material 50 is extruded through another extruder 51, each with their own thermoplastic heating systems 52, 53, such that the discharge mouth 45 of the co-extruder 55 produces multiple layer polymeric tile preforms 46, as shown.

The other details of the apparatus as shown in FIGS. 13 and 14, including the guillotine, anvil, conveyor belt, rollers, etc. are all otherwise similar to the comparable items described above with respect to FIGS. 11 and 12.

The conveyor can have a take-off speed that is matched to the extrusion speed, such that after extrusion of a given length, the cutting is affected by the guillotine or the like, and the speed of the conveyor can be controlled. Alternatively, two conveyors can be disposed serially, with the speed of the upper run of the first conveyor being accelerated to deliver the polymeric tile preforms to the second conveyor after cutting, with the speed of the first conveyor then being re-set to match the extrusion speed of extrudate leaving the extruder, with the second conveyor being controlled for delivery of the polymeric tile preforms to the compression mold. Of course, rather than having the delivery being automatic, the same could be done manually, if desired.

Thus, with reference to FIGS. 13 and 14, the multiple layer polymeric tile preforms 46 are delivered generally rightward, in the direction of the arrow 56.

It will be noted that the polymeric tile preforms 46 that are co-extruded as shown in FIGS. 13 and 14 are illustrated as being polymeric tile preforms comprising a core material 57 that is substantially the full length of the shapes as shown in FIG. 14, with a capstock material 58 on an upper surface thereof, that is slightly more than half the dimension of the full length of the shingle shapes 46 shown, terminating at 60 as shown. Alternatively, capstock material 58 could cover a lesser or greater portion of the upper surface, or even the entire upper surface of the polymeric tile preform.

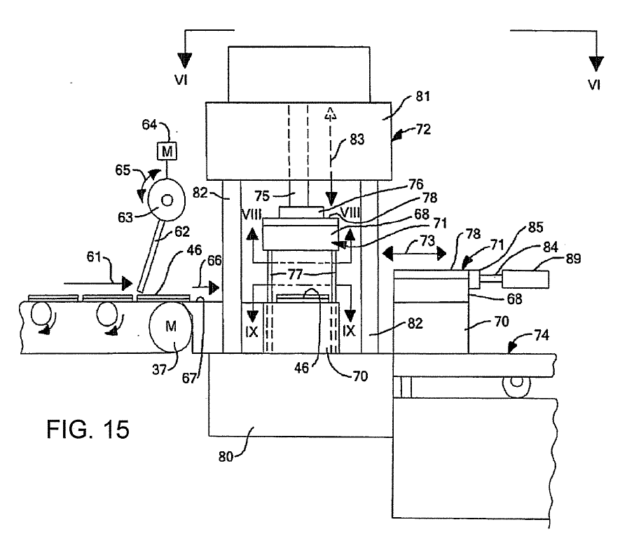

Referring now to FIG. 15, it will be seen that the polymeric tile preforms 46 or 33, as may be desired, are delivered via the conveyor belt, in the direction of the arrow 61, to be placed in a compression mold (i.e., between mold components) in a press, to be compression molded as will be described hereafter. In lieu of a conveyor belt, a moveable tray, a carrier, a platform or other techniques of supported transport could be used.

It will be noted that the extrusion and co-extrusion processes described above are continuous processes, and that the severing of the extrudate of whichever form by the guillotine is a serial, or substantially continuous process, and that the delivering of the polymeric tile preforms from the extruder or co-extruder along the conveyor belt allows for the dissipation of heat resulting from the extrusion process, from the polymeric tile preforms, in that, by allowing the shapes to substantially cool prior to placing them in the mold, rather than requiring the cooling to take place completely in the compression mold itself, reduces the required time for residence of the shapes in the compression mold during the compression process, as will be described hereinafter.

It will also be noted that maintaining the temperature above a melting temperature of the material(s) of the polymeric tile preform so that a quick flow of the melt can occur in the compression mold is desired in some embodiments. The maintaining of temperature above a crystallization or solidification temperature of the material(s) of the polymeric tile preform can minimize the development of internal stresses within the polymeric tile preforms that could be caused by deformation of polymers that have begun to enter the solid state.

As the polymeric tile preforms approach the right-most end of the conveyor belt as shown in FIG. 15, some suitable device, such as the pusher rod 62, shaft-mounted at 63 and suitably motor-driven by motor 64, and operating in a back-and-forth motion as shown by the double-headed arrow 65, pushes polymeric tile preforms 46 (or 33) rightward, in the direction of the arrow 66, along table 67, to the position shown, between upper and lower mold components 68, 70, respectively. A photovoltaic element (not shown for the sake of simplicity) is also placed in the compression mold.

In some embodiments of the invention, the compression mold generally designated 71 in FIG. 15 and including upper and lower mold components 68 and 70, respectively, is movable into and out of its position as shown at the center of the ram mechanism 72, in the direction of the double-headed arrow 73, from an indexable table 74 that will be described hereinafter. The ram mechanism 72 operates like a press, wherein a ram 75 is pneumatically, hydraulically or electrically driven, generally by use of a piston or the like within the upper end of the ram mechanism, for driving an electromagnet 76 carried at the lower end of the ram 75, for lifting the upper mold component 68 upwardly as shown.

The closing of the compression mold can be done, at a force of, for example, 40 tons, in order to cause a material flow out on the edges of the unfinished photovoltaic roofing tile being molded, for 3-4 seconds, with the entire molding process as shown in FIG. 15 taking approximately one minute, after which the cooling of the unfinished photovoltaic roofing tile can take place, followed by removal of the unfinished photovoltaic roofing tile from the mold, for subsequent or simultaneous trimming of the flashing therefrom. Shorter molding cycles of less than 45 seconds, less than 20 seconds or even less than 15 seconds can also be used.

The two mold components 68 and 70, when moved from the closed position on table 74 shown at the right end of FIG. 15, to the open position shown at the center of the ram mechanism 72 of FIG. 15, separate such that the upper component 68 is movable upwardly and downwardly along guide rods 77, as the electromagnet 76 lifts a preferably ferromagnetic cap 78 carried by the upper mold component 68, such that, in the open position shown for the compression mold 71 in FIG. 15, a transfer mechanism (e.g., a pushrod 62) may move a polymeric tile preform 46 (or 33) along the table 67 in the direction of the arrow 66, to a position between the open mold components 68, 70 as shown. Of course, other techniques can be used to open the compression mold, such as mechanical separation.

The ram mechanism 72, itself, is comprised of a base member 80 and a compression member 81, and the member 81 carries the ram 75. The compression member 81 also moves vertically upwardly and downwardly, via its own set of guide rods 82, in the direction of the double-headed arrow 83, and is suitably driven for such vertical movement by any appropriate mechanism, such as hydraulically, pneumatically, electrically or mechanically (not shown).

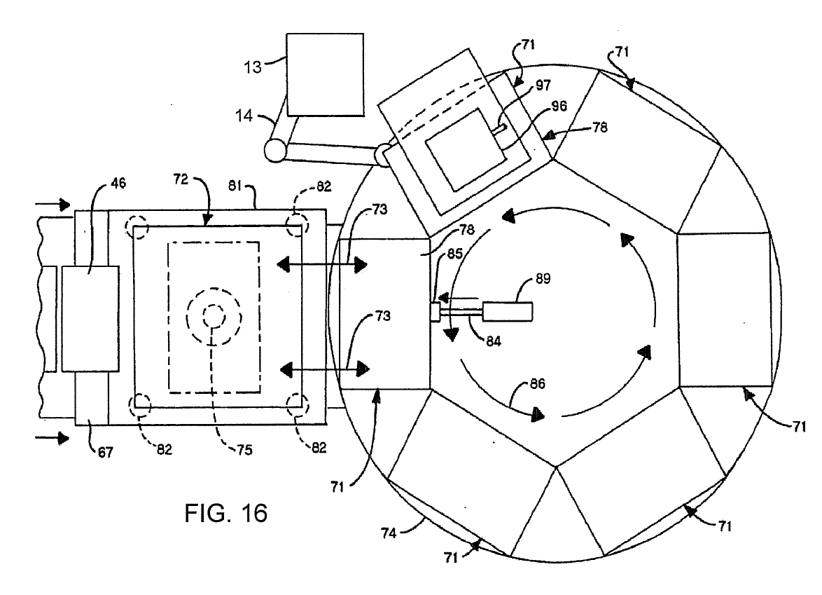

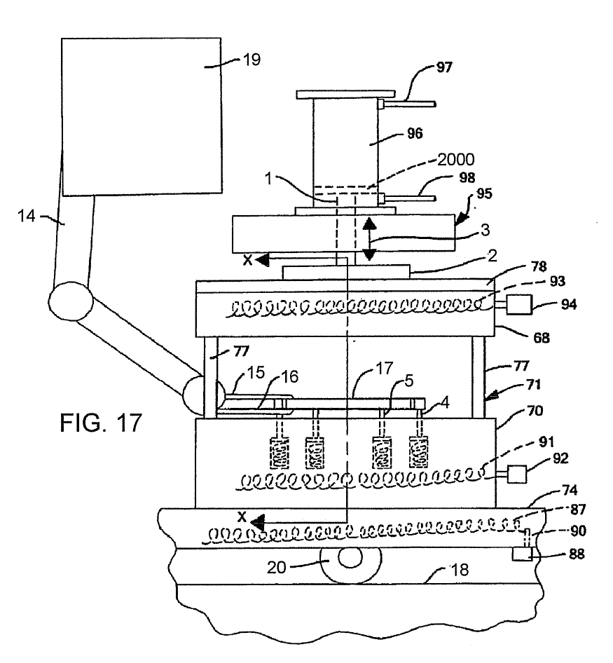

With reference now to FIGS. 16 and 17, it will be seen that the compression mold 71 can be moved to and from the ram mechanism 72, in the direction of the double-headed arrow 73, by any appropriate technique, such as by use of a hydraulic or pneumatic push/pull cylinder 89, driving a rod 84, that in turn has an electromagnetic push/pull plate 85, for engaging the ferromagnetic cap 78 of the upper mold component 68, as shown in FIGS. 15 and 17.

The indexable table 74 is rotatably driven by any suitable technique (not shown), to move compression molds 71 into position for delivering them to and from the ram station 72 as discussed above. In this regard, the indexable table 74 may be moved in the direction of the arrows 86.

If desired, in order to facilitate cooling, cooling coils can be embedded in, or otherwise carried by the table 74, such coils being shown in phantom in FIG. 17, at 87, fed by a suitable source 88 of coolant, via coolant line 90, as shown. The coolant can be, for example, water, ethylene glycol.

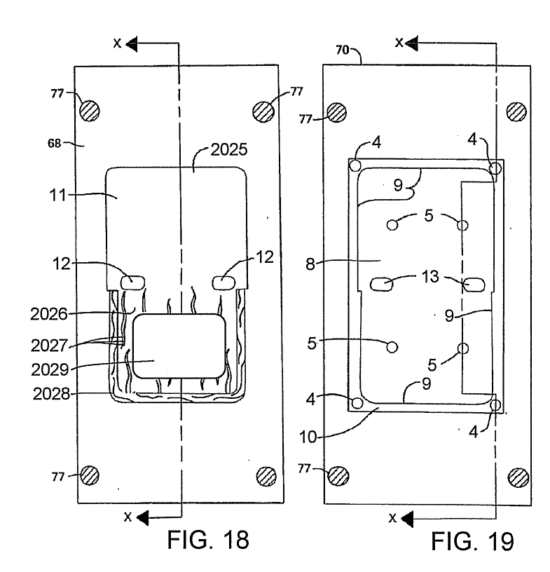

Similarly, coolant coils are shown in phantom at 91 in FIG. 17 for the lower mold component 70 and can be provided with coolant from a suitable source 92, if desired. Also, optionally, the upper mold component 68 can be provided with internal coolant coils 93, shown in phantom in FIG. 18, likewise supplied by coolant from a suitable source 94.

In some embodiments of the invention, within the compression mold, the top mold component 68 (which engages the capstock material) is heated to a slightly greater temperature than that of the bottom component 70, in order to control internal stress development. For example, the top component 68 may be heated to 120° F., with the bottom component being heated to 70-80° F. The subsequent cooling for the top plate 68 can be a natural cooling by simply allowing heat to dissipate, and the bottom plate can be cooled, for example, by well water, at about 67° F. Alternatively, well water or other coolant could be circulated, first through the bottom component 70 and then to the top component 68; however, in some instances both components 68 and 70 can be cooled to the same temperature. Of course, various other cooling techniques can be employed to regulate temperature at various locations in the compression mold, depending upon the thickness of the photovoltaic roofing tile being molded, and in various locations of the photovoltaic roofing tile being molded.

At one of the stations shown for the indexable table 74, a lifting mechanism 95 can be provided, for opening the compression molds 71, one at a time. A typical such lifting mechanism can include a hydraulic or pneumatic cylinder 96, provided with fluid via fluid lines 97, 98, for driving a piston 2000 therein, which carries a drive shaft 1 that, in turn, carries an electromagnet 2 for engaging the cap 78 of the upper mold component 68, as the drive shaft 1 is moved upwardly or downwardly as shown by the double-headed arrow 3.

The closing of the components 68 and 70 relative to each other could alternatively be done under a force of 30 tons, rather the 40 tons mentioned above, in order to obtain a consistent closing and flow of material. Alternatively, the closing could begin at a high speed, and then gradually slow down, in order get an even flow at an edge of the shape that is being formed into a shingle. Of course, other forces and closing speed profiles can be used in performing the methods and making the photovoltaic roofing elements of the present invention.

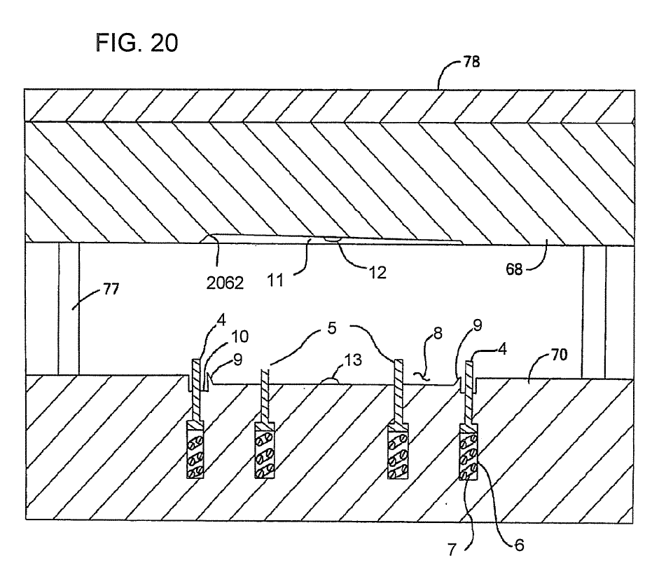

When the compression mold 71 is in the open position shown in FIG. 17, and as is shown in greater detail in FIG. 20, a plurality of spring pins 5, mounted in lower mold component 70, in generally cylindrical cavities 6 thereof, are pushed upwardly by compressed springs 7, such that the upper ends of the spring pins engage the compression molded shingle and pushed the same out of the lower mold cavity 8.

Similarly, spring pins 4 engage “flashing”, or other material that has been cut away from the periphery of the formed shingle, for pushing the same out of the trench 10 that surrounds the cavity 8 in the lower mold component 70.

As shown in FIGS. 19 and 20, in one embodiment of the invention, the lower mold 70, has, at the periphery of its cavity 8, an upstanding cutting blade 9 separating the mold cavity 8 from the peripheral trench 10, for cutting the polymeric tile preforms placed therein to the precisely desired dimensions of the final photovoltaic roofing tile, during the compression molding process. That is, generally, the polymeric tile preforms may be slightly larger in size than the final photovoltaic roofing tile shape, to enable the cutting edge 9 to achieve the final desired dimensions for the photovoltaic roofing tile. The cutting of flashing from the photovoltaic roofing tile should be done quickly, and it is preferably done in the compression mold. The flashing can be recycled back for re-use, most preferably for use as part of subsequent core material. The flashing can also be trimmed during the molding process itself, in certain embodiments of the invention, when the compression mold is totally closed, cooperating surfaces on the upper mold component and the lower mold component cut any flashing away. While the trimming of the flashing can be done in the compression mold, it could, alternatively, be done as a secondary trimming and finishing operation which, in some cases may be more cost effective than trimming in the compression mold.

Both the upper and lower mold cavities 11 and 8 can be provided with protrusions 12, 13, respectively, which protrusions will form reduced-thickness nailing or fastening areas in the compression molded shingle, as will be described hereinafter. The upper and lower mold cavities can also be provided with any protrusions or recesses necessary to form other features on the photovoltaic roofing tile. For example, the lower mold cavity can be provided with a protrusion in order to form a hollowed-out polymeric carrier tile, and with recesses to form ribs, as shown in the photovoltaic roofing tile of FIG. 4.

With the fully formed unfinished photovoltaic roofing tile as shown in FIG. 17 having been lifted upwardly out of a lower mold component 70 by the spring pins, a computer control robot mechanism 19 or the like may control a robotic arm 14, having tile-engaging fingers 15, 16, adapted to engage upper and lower surfaces of the unfinished photovoltaic roofing tile 17, and move the same horizontally out from between upper and lower mold components 68, 70, to another location for storage or delivery to another station.

Thereafter, the indexable table 74 can be moved, for delivery of a next adjacent compression mold to the station for engagement by the lift mechanism 95, with the table 74, generally being rotatable on a floor 18, as allowed by a number of table-carrying wheels 20.

Referring now to FIGS. 18 and 19, specifically, the upper mold component 68 (FIG. 17) can have a generally rectangular shaped upper mold cavity 11 that is essentially the shape of a natural slate shingle having a headlap portion 2025 and a butt or tab portion 2026. It will be noted that in the headlap portion there are a plurality of protrusions 12 that define reduced thickness areas in the compression molded shingle 17, to serve as nailing or fastening areas, to make it easier for nails or other fasteners to penetrate the shingle 17 when it is nailed to a roof.

There are also a plurality of mold recesses or protrusions 2027 as may be desired, to build into the shingle 17 the appearance of a natural slate, tile or the like. It will be understood that the number and style of the recesses/protrusions 2027 will be varied to yield a natural-appearing shingle having the desired aesthetics.

The compression mold can also include a feature configured to embed the photovoltaic element into the polymeric carrier tile at a controlled depth. For example, the upper mold cavity shown in FIG. 18 has a slight recess 2029 into which the photovoltaic element fits during molding; the depth of the recess can be selected with reference to the thickness of the photovoltaic element to control the depth of the indentation formed in the polymeric carrier tile.

In the tab or butt portion 2026, there is a gradually sloped reduced-thickness portion 2028 that appears in FIG. 18 to be U-shaped, and which defines the periphery thereof. This sloped reduced-thickness portion (2028 in FIGS. 18 and 565 in FIG. 5) will serve to cause the capstock layer of the polymeric tile preform being engaged, to flow peripherally outwardly around the edges of the core layer of material, such that, in the finished photovoltaic roofing tile, the exposed edges will be covered by capstock material, as well as the exposed surface, such that the edges of the core layer of photovoltaic roofing tile are weather-protected.

With reference to FIG. 19, it will be seen that the lower mold component 70 is provided with a lower mold cavity 8, also having protrusions 13 therein, for effecting a reduced-thickness (or other geometry) nailing or fastening area for application to a roof, in the final photovoltaic roofing tile 17. The lower mold component can also, for example, include features to create the hollowed-out bottom surface and/or ribs shown in FIG. 4. Of course, the mold cavity 11 could be the lower mold cavity and that the mold cavity 8 could be the upper mold cavity, if desired.

The spring pins 4, 5, and the trough 10 and mold depression 8, respectively, as described previously, are also shown in FIG. 20.

It will thus be seen that the two mold components 68 and 70 are thus adapted to compression mold a photovoltaic roofing tile such as that which is shown by way of example only, in FIG. 5.

As described above, the process described with reference to FIGS. 11-20 can be performed to compression mold a photovoltaic element into the surface of the polymeric carrier tile. As the person of skill will appreciate, the process can also be performed to mold an indentation into the surface of the polymeric carrier tile (for example, using a specially-shaped mold or a dummy insert or template). A photovoltaic element (e.g., a laminate structure as described above) can then be placed in the indentation and affixed (e.g., by pressure and/or heat) therein.

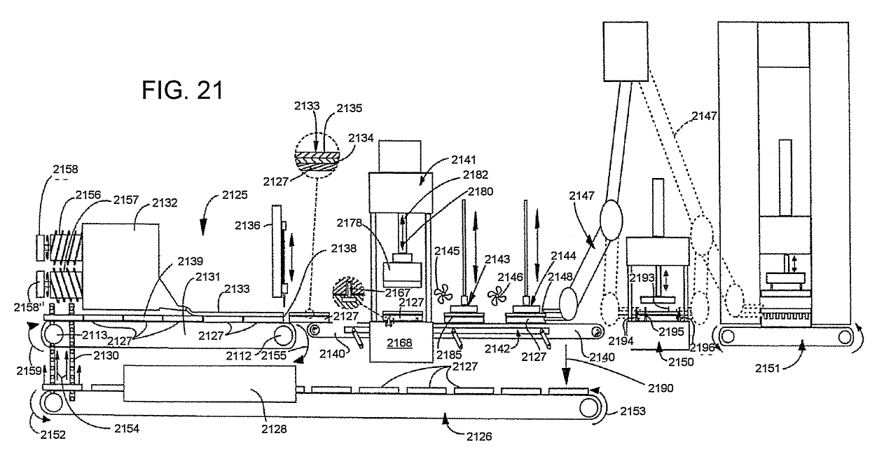

Other embodiments of a manufacturing process are similar to the above-described process, but uses carrier plates to carry the workpiece through the process, as well as to serve as the lower mold component of the compression mold. These embodiments are described with respect to FIGS. 21-49 below, and more generally in International Patent Application no. PCT/US07/85900, which is hereby incorporated herein by reference in its entirety. In certain embodiments of the invention, the material of the polymeric tile preforms is extruded directly onto a series of carrier plates, which preferably have been pre-heated. The material is severed between each carrier plate to form polymeric tile preforms, which are then delivered to a compression mold of the short cycle type. A photovoltaic element is inserted into the compression mold, for example by being introduced to the compression mold before or after the polymeric tile preform; or by being placed on the top surface of the polymeric tile preform before it is delivered to the compression mold. The compression mold has an upper mold component having a desired upper mold cavity, as described above. The lower mold component is formed from the surface of the carrier plate. The polymeric carrier tile and the photovoltaic element are molded together in the compression mold to form an unfinished photovoltaic roofing tile. The unfinished roofing tile is removed from the carrier plate and placed on a secondary plate, where any flashing from the compression molding is removed. The unfinished roofing tiles thus formed are delivered to a cooling zone. In the cooling zone, a curvature can be provided to the photovoltaic roofing tile, for example by sandwiching the unfinished photovoltaic roofing tile between upper and lower plate components of a retention mechanism while it cools. Of course, in other embodiments of the invention, for example those in which a rigid photovoltaic element is used, no additional curvature need be imparted to the photovoltaic roofing element.

Referring now to FIGS. 21-49 in detail, reference is first made to FIG. 21, in which an apparatus useful in making polymeric carrier tiles is generally designated by numeral 2125. In the description of FIGS. 21-49, the molding methods are generally described as creating “polymeric carrier tiles.” As the person of skill in the art will appreciate in the context of the present specification, the polymeric carrier tile can be fabricated in the molding process to have a photovoltaic element molded therewith to form a photovoltaic roofing tile. Alternatively, as described above, the process can also be performed to mold an indentation into the surface of the polymeric carrier tile (for example, using a specially-shaped mold or a dummy insert or template). A photovoltaic element (e.g., a laminate structure as described above) can then be placed in the indentation and affixed (e.g., by pressure and/or heat) therein.

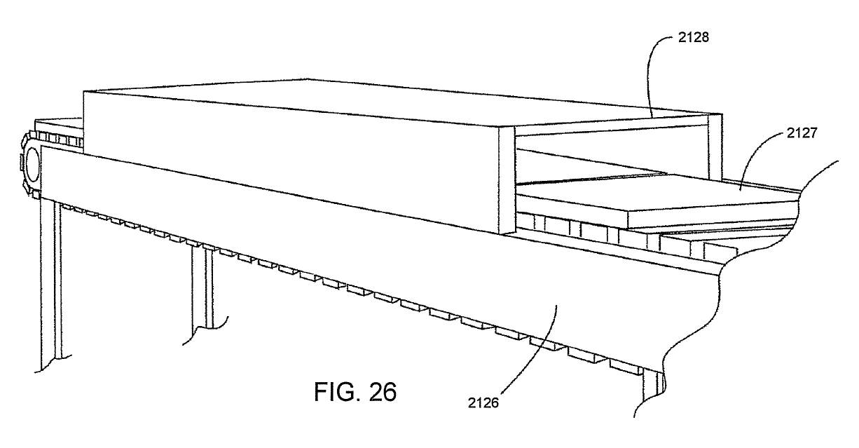

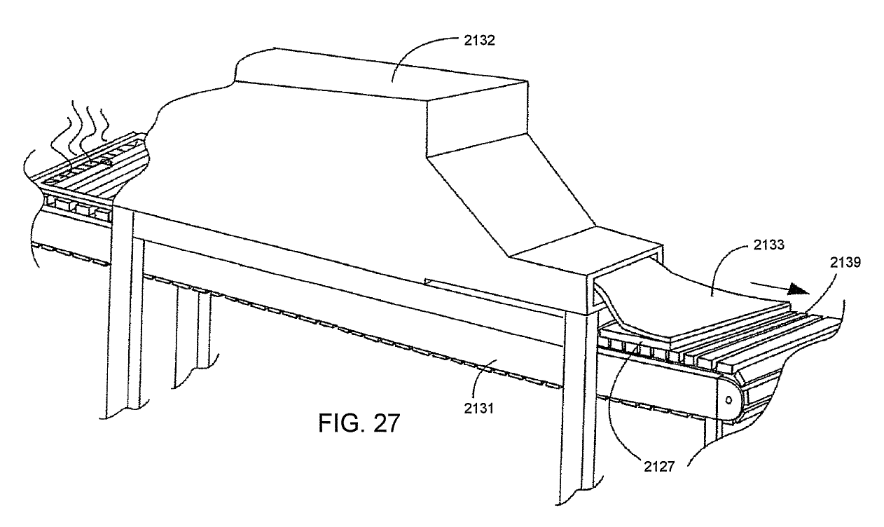

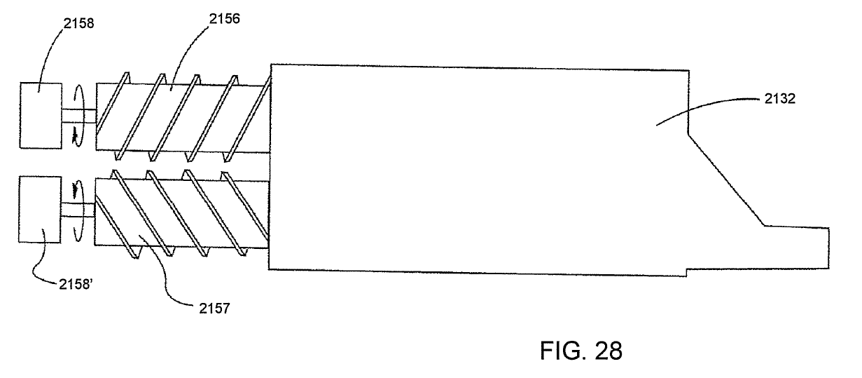

Apparatus 2125 comprises a preliminary conveyor apparatus 2126 for delivering carrier plates 2127 through a carrier plate preheater apparatus 2128, as shown in perspective view in FIG. 26, whereby the carrier plates are delivered via a transfer mechanism 2130 to an extruder conveyor apparatus 2131 between rotatable end shafts 2112, 2113, whereby the carrier plates are delivered beneath an extruder apparatus 2132, shown in larger view in FIG. 28, of the type preferably having a pair of single screw extruders 2156, 2157, by which a co-extruded sheet of polymeric tile preform material 2133, preferably comprised of a core material 2134 covered by a layer of capstock material 2135 is co-extruded onto the carrier plates 2127, as is shown more clearly in perspective view in FIG. 27, and the carrier plates are delivered end-to-end therebeneath, as shown in FIG. 21.

The carrier plates with the polymeric tile preform material 2133 thereon are then delivered past a severing mechanism 2136, for severing the polymeric tile preform material at an end 2138 of a carrier plate.

The carrier plates 2127 are then delivered to a speed-up conveyor 2140, at which the carrier plates are serially separated one from the other, for serial delivery to a compression mold 2141.

A walking beam type transport mechanism 2142 lifts the carrier plates from the conveyor mechanism 2140, into the compression mold 2141 and subsequently out of the compression mold 2141, to be transferred by the walking beam mechanism 2142 to a series of hold-down stations 2143, 2144, each of which have associated cooling devices 2145, 2146 for cooling down the still soft, compression molded polymeric carrier tiles. The carrier plates 2127 are then transferred downward, as shown by the arrow 2190 from the conveyor 2140, back to the return conveyor 2126, for re-use.

As the person of skill will appreciate, a photovoltaic element can be positioned on the extruded polymeric tile preform material before molding, optionally with a heating step to activate any adhesive provided therebetween. In such a process, the molded polymeric carrier tile would be part of a photovoltaic roofing tile also including the photovoltaic element. In other embodiments of the invention, an insert or template can be positioned on the extruded polymeric tile preform material before molding, then removed after molding to provide an indentation into which a photovoltaic element can later be positioned and affixed. The compression mold can also itself form the indentation.

It will be understood that the extruders 2156, 2157 could feed multiple compression molds 2141, such as anywhere from two to four compression molds, in some desired sequence, via a plurality of stepped-up conveyors 2140, if desired, or in any other manner, and in some operations such could be a preferred embodiment.

A transfer mechanism 2147, which may be of the robot type, is provided for lifting a molded polymeric carrier tile 2148 from its carrier plate 2127, and delivering the polymeric carrier tile 2148 to a severing station 2150 for removing flashing therefrom. At the severing station 2150, the polymeric carrier tile 2148 is placed onto a secondary plate where blades will trim flashing from the various edges thereof, as will be described more fully hereinafter.

The robotic or other type of mechanism 2147 will then remove the polymeric carrier tile from the flash trimming station 2150 and deliver it to a cooling station 2151 as will also be described in detail hereinafter, and wherein the polymeric carrier tile is cooled down to ambient temperature, and in one embodiment provided with a curvature therein.

At the left lower end of FIG. 21, it will be seen that a representative mechanism 2130 illustrates the manner in which carrier plates 2127 can be delivered from the upper run of the conveyor mechanism 2126, which conveyor mechanism is moving in the direction of the arrows 2152, 2153, to lift the carrier plates 2127 upwardly in the direction of the arrows 2154, to place the same onto the upper run 2139 of the conveyor 2131, which conveyor 2131 is being driven to move its upper run in the direction of the arrows 2155, 2159.

With the carrier plates 2127 being moved rightwardly with the upper run of the conveyor 2131 as shown in FIG. 21, to pass beneath the co-extruder 2132, it will be seen that a pair of single screw extruders 2156, 2157, being motor driven by motors 2158, 2158′, produce a multi-layer extrudate comprising a core layer 2134 and a capstock layer 2135 of soft, semi-molten polymeric tile preform material 2133 onto a series of carrier plates 2127 that are passing beneath the extruder 2132, end-to-end, as shown in FIGS. 21 and 27 for example.

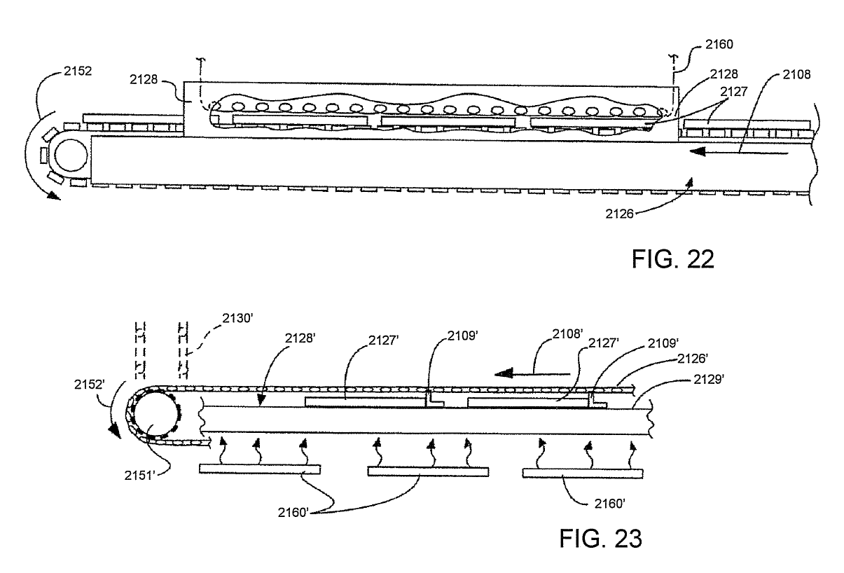

With reference to FIG. 22, it will be seen that the preheater 2128 can be provided with any suitable heater mechanism 2160 for preheating the carrier plates 2127 as they pass therethrough. The heating mechanism 2160 can be an electric heater, a heated fluid passing through a pipe or tube, an infrared heater, a microwave heater, or any other suitable heating device, such as a hot air blower, or a combination of heating mechanisms if desired.

In FIG. 23 an alternative embodiment of a preheater 2128′ is provided, wherein carrier plates 2127′ are delivered leftward along a preferably steel plate 2129′ (fragmentally shown) with heating elements 2160′ disposed therebeneath for heating the plate 2129′ for transferring heat to the carrier plates 2127′. The carrier plates are moved along the plate 2129′ by movable brackets 2109′ of angle iron or other types, in the direction of arrow 2108′, which are driven from the opposite side of the preheater 2128′ to that shown in FIG. 23 by a conveyor chain 2126′ (fragmentally shown), in turn driven by sprockets 2151′ at ends thereof, turning in the direction of the arrow 2152′. A transfer mechanism 2130′ (shown in phantom), like the transfer mechanism 2130 of FIG. 21, lifts the carrier plates 2127′ upwardly at the left end of the preheater 2128′ to pass beneath the extruder 2132. The heating elements 2160′ can be any of those described above with reference to FIG. 22. Supplemental heating elements (not shown) can also be used, and they can be infrared elements, quartz lamps, or any other heater suitable to heat the plate 2129′ or the carrier plates 2127′.

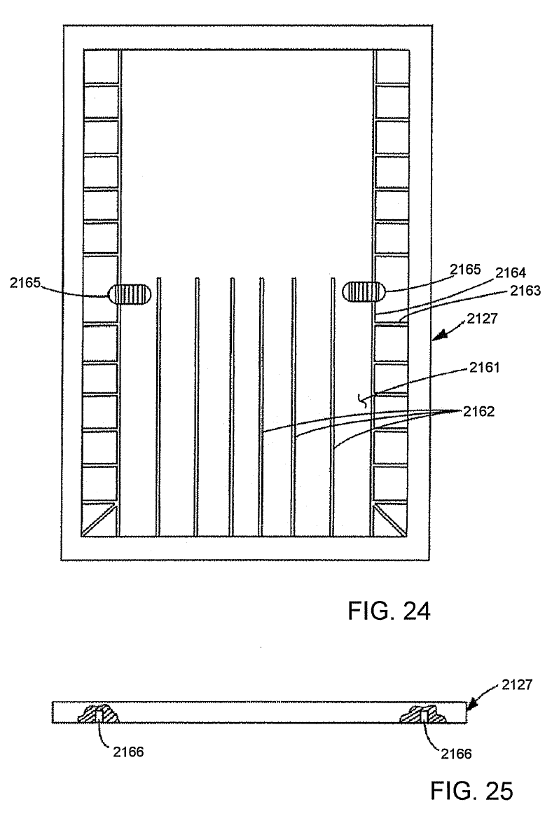

With reference to FIGS. 24 and 25, it will be seen that the carrier plates 2127 will each have an upper surface 2161, preferably, with a plurality of grooves 2162, 2163, 2164, etc., and preferably fastening zones 2165, molded therein, configured to the reciprocal of the configuration of the underside of polymeric carrier tiles to be formed thereon, such that the undersides of the polymeric tile preforms will have their material entering the grooves 2162-2164 and fastening zones 2165, to provide suitable spacing ribs and fastening zones (not shown) for the underside so the polymeric carrier tiles to be formed on the carrier plates 2127, with the ribs serving to support polymeric carrier tiles mounted on roofs. Alternatively, the carrier plates could be solid, if desired. Also, alternatively, other features may be provided on the upper surfaces of carrier plates 2127 to impart reciprocal features to the polymeric carrier tiles molded thereby.

With specific reference to FIG. 25, it will be seen that the carrier plates 2127 may have carrier pin holes 2166, to facilitate the proper placement of the carrier plates 2127 over pins 2167 as shown in FIG. 21 in the bottom 2168 of the compression mold 2141, when the carrier plates are delivered to the compression mold 2141, for proper and precise location of the carrier plates 2127 in the compression mold 2141.

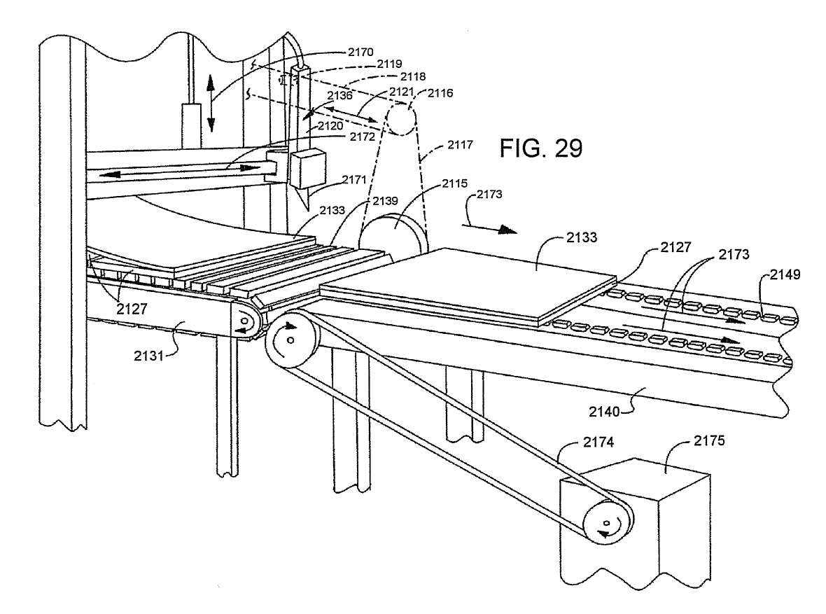

With reference now to FIGS. 21 and 29, the placement of the extrudate 2133 onto a serially arranged and touching number of carrier plates 2127 is illustrated at the outlet of the extruder, as is the severing mechanism 2136 by which the polymeric tile preform material 2133 is serially severed at each endwise location of a carrier plate.

The severing mechanism 2136 operates such that it can be lowered or raised as indicated by the direction of the double headed arrow 2170 shown in FIG. 29, with a severing blade 2171 thereof being moved transversely of the upper run 2139 of the conveyor 2131, in the direction of the double headed arrow 2172, to traverse the conveyor upper run 2139, to sever the polymeric tile preform material 2133 as shown in FIG. 6, to overlie each carrier plate 2127.

The severing mechanism 2136 may optionally be longitudinally moveable in correspondence with the longitudinal movement of the carrier plates, as shown in phantom in FIG. 29, via a pulley or the like 2115, rotating in unison with shaft 2112, and in turn, driving a belt or chain 2117 that in turn, is driving a shaft 2116 that drives a longitudinal conveyor 2118 connected at 2119 to a post 2120 of the severing mechanism 2136, so that the mechanism 2136 is longitudinally movable in the direction of the double headed arrow 2121. This enables tracking of the severing mechanism 2136 with the progress of the carrier plates 2127 along the conveyor system, so that the precision of the cut is maintained.

Following the severing by the mechanism 2136, the conveyor 2140 is driven such that its upper run 2149 moves in the direction of the arrow 2173, at a faster rate than the upper run 2139 of the conveyor mechanism 2131, such that the carrier plates 2127 become separated from each other.

The conveyor upper run 2149 may be driven in any suitable matter, such as being belt driven as at 2174 from a motor 2175, or in any other manner, as may be desired.

Optionally, a plurality of extruder apparatus 2132 and severing mechanisms 2136 may, if desired, be used to supply extruded polymeric tile preform material 2133, disposed on carrier plates 2127, to any selected ones of a plurality of compression molds 2141, as may be desired.

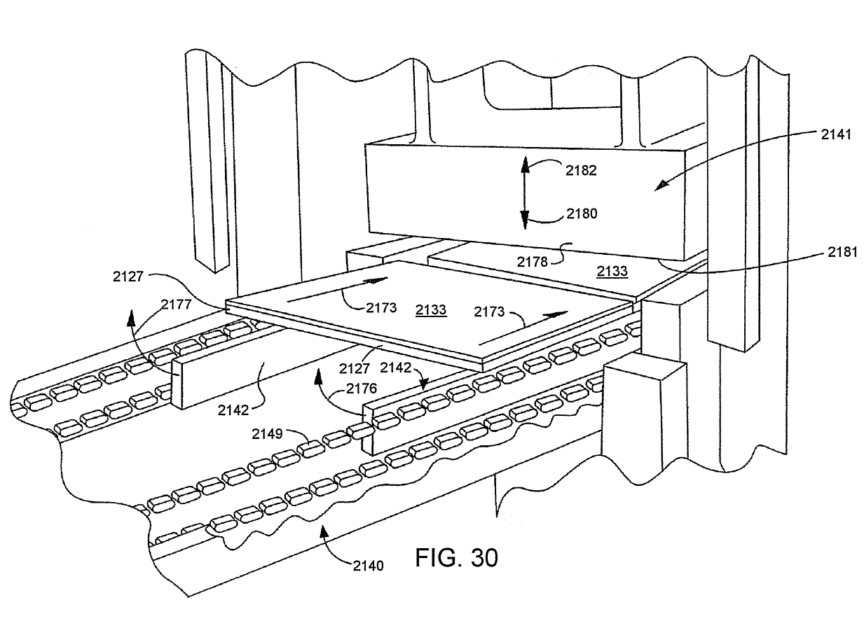

With reference now to FIGS. 21 and 30, it will be seen that the carrier plates 2127 with their polymeric tile preform material 2133 applied thereto are delivered along the upper run 2149 of the conveyor mechanism 2140, to the walking beam transport mechanism 2142, which is operated to be lifted upwardly as shown by the arrows 2176, 2177, to lift the carrier plates 2127 into the compression mold 2141, to place the carrier plates 2127 onto a base mold portion 2168 thereof, by which the pin recesses 2166 (FIG. 25) may be engaged by upstanding pins 2167 in order to properly secure the location of the carrier plates and the polymeric tile preform material 2133 thereon in the compression mold 2141. Thereafter, the upper die portion 2178 of the compression mold 2141 is moved vertically downwardly in the direction of the arrow 2180, such that its lower surface 2181, being configured to have a reciprocal surface configuration to that which is desired for the upper surface of the polymeric carrier tile that is to be molded on the carrier plate 2127, engages the polymeric tile preform material 2133 under a predetermined pressure to force the polymeric tile preform material 2133 to conform to the reciprocal of the surface configuration 2181 of the die 2178, and thereafter, the die 2178 is moved upwardly in the direction of the arrow 2182 of FIG. 30 such that the then molded polymeric carrier tile is ready for discharge from the compression mold 2141. The use of the carrier plates enables supporting the polymeric carrier tile material for a shorter time in the compression mold than if the polymeric carrier tile material had to be released from the mold when it is more solidified and therefore more self-supporting.

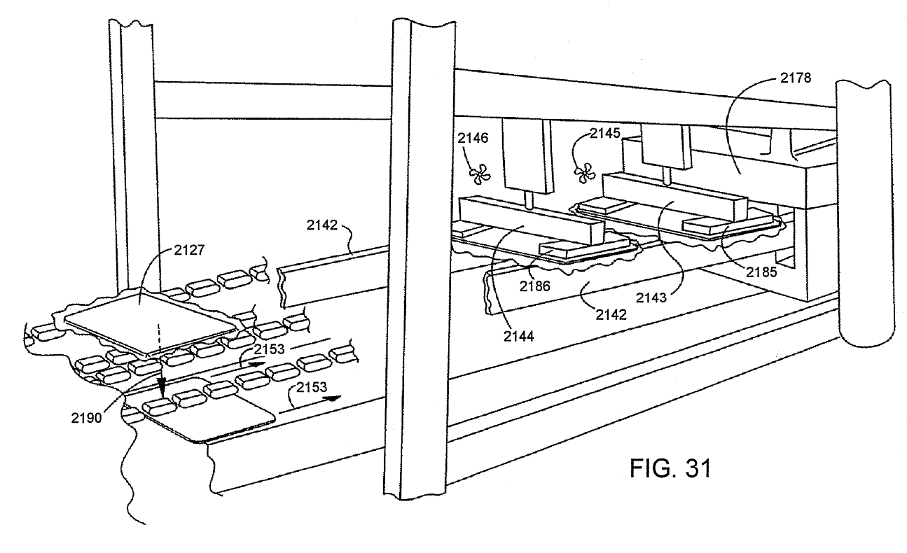

A lifting motion of the walking beam mechanism 2142 then lifts the carrier plate 2127 and the polymeric carrier tile molded thereon from the compression mold 2141 and sequentially delivers the same to the two hold-down stations 2143, 2144 as shown in FIGS. 1 and 31. At the hold-down stations 2143, 2144, the thus formed polymeric carrier tiles and carrier plates are engaged by respective hold-down members 2185, 2186, and cooling air may be delivered via optional fans or the like, 2145, 2146 to facilitate a partial cooling-down of the thus-formed polymeric carrier tiles.

After leaving the hold-down stations 2144, the robot or other mechanism 2147 or an operator (manually) picks up a thus-formed polymeric carrier tile off its carrier plate 2127 and delivers the same as shown by the full line and phantom positions for the robot mechanism 2147 illustrated in FIG. 21, onto a secondary plate 2187 (FIG. 32) of the flash-trimming mechanism 2150.

With reference to FIGS. 21 and 32, the flash-trimming mechanism 2150 is more clearly illustrated.

Upon separation of a thus-formed polymeric carrier tile 2133 from its carrier plate 2127, the carrier plate becomes disengaged from the conveyor mechanism 2140, and drops down as shown by the arrow 2190 in FIG. 21, to the upper run of the conveyor mechanism 2126 for re-use.

Upon placement of the polymeric carrier tile on the secondary plate 2187 in the flash-trimming mechanism 2150, an upper plate 2191 is brought vertically downwardly in the direction of the arrow 2192, to engage the upper surface of the thus-formed polymeric carrier tile 2133, such that four severing blades 2193, 2194, 2195, 2196, may simultaneously be moved along the edges of the secondary plate 2187, in the directions of the arrows 2197, 2198, 2200 and 2201, respectively, to sever flashing 2202 therefrom, after which the plate 2191 is lifted upwardly in the direction of arrow 2203, and the robot arm 2147 or a different mechanism (not shown) or an operator (manually) engages the thus trimmed polymeric carrier tile 2133 and removes it from the flash trimming station 2150.

Alternatively, the severing blades 2193-96 could be driven to flash-trim in directions opposite to directions 2197, 2198, 2200 and 2201, or both in the directions 2197, 2198, 2200 and 2201 and in directions opposite thereto, in back-stroke directions.

With reference to FIGS. 21, 33 and 34 more specifically, the apparatus and method for cooling the polymeric carrier tiles thus formed in a cooling tower is more clearly illustrated.

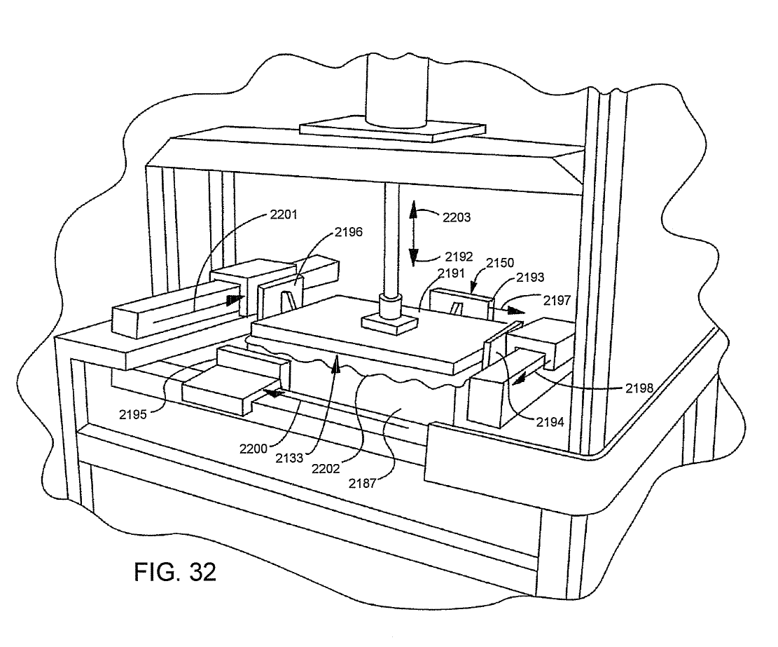

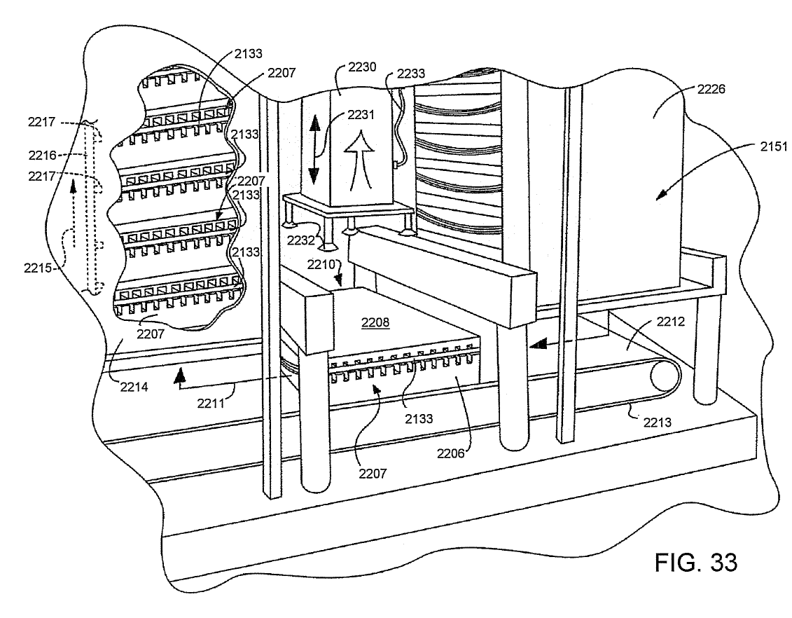

As shown toward the right side of FIG. 21, particularly in phantom, the robotic arm 2147 engages a polymeric carrier tile 2133 from the trimming mechanism 2150 and inverts the polymeric carrier tile, so that its upper face (which is the face that will be facing upwardly when installed on a roof) is facing downwardly, delivering the same to cooling tower 2151. With reference to FIG. 33, the polymeric carrier tile 2133 is then facing downwardly against a preferably ridged upper surface 2205 of a lower component plate 2206, as shown in FIG. 35 of a retention mechanism generally designated by the numeral 2207. The retention mechanism 2207 comprises a lower component plate 2206 and an upper component plate 2208, sandwiching the polymeric carrier tile between the plates 2206 and 2208. This occurs at a loading station 2210 as shown in FIG. 33. The ridged surfaces 2205 enable airflow for cooling. Other shaped surfaces that facilitate airflow for cooling could be used, as alternatives.

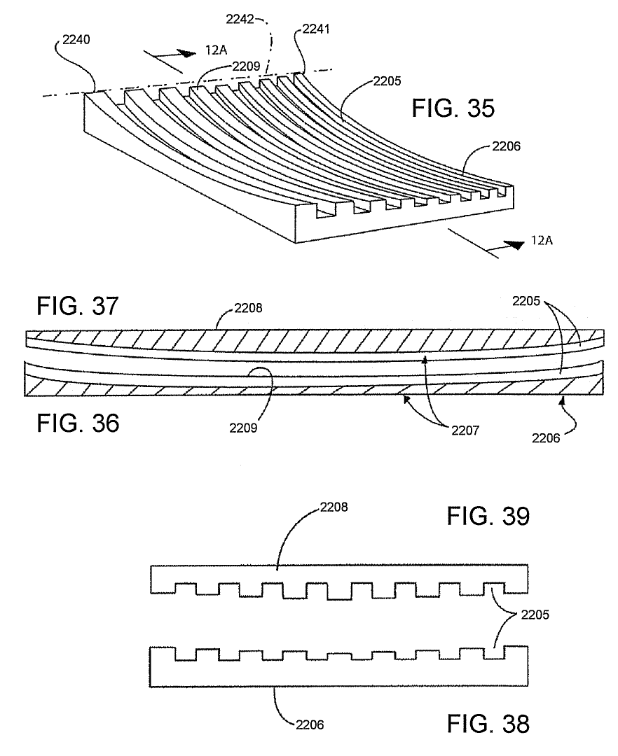

Alternatively, the polymeric carrier tiles 2133 could be engaged by their robotic arm 2147 and not inverted, but placed between opposed plates 2106, 2108 that have downwardly curved opposing surfaces, opposite to those curved surfaces shown in FIGS. 36 and 37.

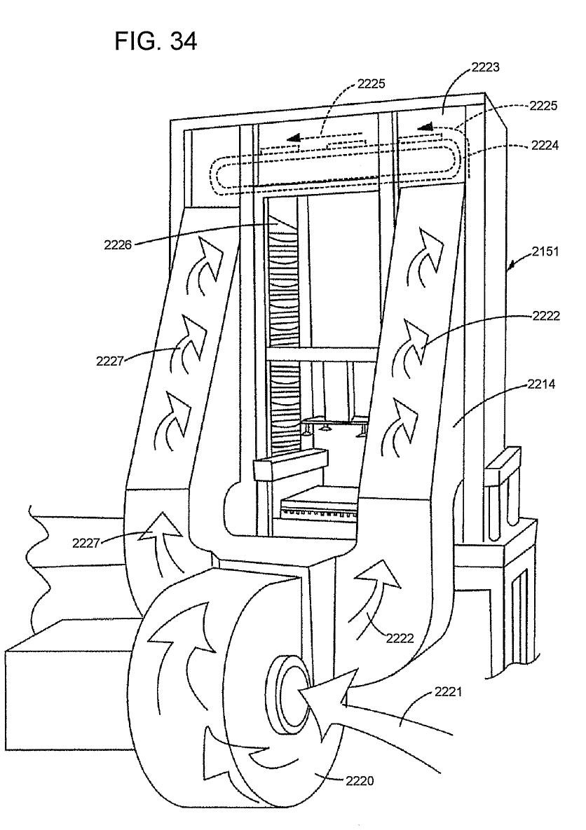

After a polymeric carrier tile is thus sandwiched between upper and lower component plates 2208 and 2006 of the retention mechanism 2207, the retention mechanism 2207 is moved in the direction of the arrow 2211 of FIG. 33, along the upper run 2212 of a conveyor 2213, to the left side 2214 of the cooling tower mechanism 2151 illustrated in FIG. 33. In the left side 2214 of the cooling tower mechanism 2151, a plurality of retention mechanisms 2207 with polymeric carrier tiles 2133 carried therein are lifted vertically upwardly, in the direction of the phantom arrow 2215, via an upward conveying device 2216 having engagement lugs 2217 carried thereby, during which cooling air is delivered via a fan or the like 2220 (FIG. 34) with ambient air being drawn into the fan in the direction of the arrow 2221, passing upwardly in the direction of the arrows 2222, and through the grooves of the ridged surfaces 2205 (FIGS. 35-39) in the upper and lower component plates 2208, 2206 of the retention mechanisms 2207, to cool the polymeric carrier tiles 2133 disposed therein.

After the polymeric carrier tiles are conveyed fully upwardly through the left tower portion 2214 of FIG. 33, to the upper end 2223 thereof (FIG. 34), they are delivered across the top of the tower mechanism 2151 via a suitable conveyor (shown in phantom) 2224 or the like, in the direction of the arrows 2225, to a downwardly conveying portion 2226 of the cooling tower, wherein they are conveyed downwardly in a manner similar to that which they are conveyed upwardly in tower portion 2214, so the same will not be duplicated by way of explanation herein.

During the downward passage of the retention mechanisms through tower portion 2226, cooling air is likewise delivered from the fan 2220, with ambient air being thus delivered to the polymeric carrier tiles in the now downwardly moving retention mechanisms in tower portion 2226, with air being supplied in the direction of the arrows 2227.

At the loading station 2210 illustrated in FIG. 33, a mechanism is provided for lifting the upper component plate 2208 of each retention mechanism 2207 both onto and away from a polymeric carrier tile 2133 being carried by a lower component plate 2206 of the retention mechanism 2207. In doing so, a vertically movable lift mechanism 2230 is provided, moveable upwardly and downwardly in the direction of the double headed arrow 2231, with a plurality of feet 2232 being carried thereby for engaging upper component plates 2208, and a vacuum delivery line 2233 is provided, such that as the feet 2232 engage a plate 2208, the vacuum is actuated and applied through the feet 2232, so that upper component plates 2208 of the retention mechanisms may be lifted from or placed downwardly onto a polymeric carrier tile 2133, either for delivery to an upwardly lifting portion 2214 of the cooling tower, or for removing an upper component plate 2208 from a polymeric carrier tile retention mechanism 2207 after it is delivered downwardly via tower portion 2226, in order to access a cooled polymeric carrier tile from a retention mechanism 2207.

When the hot, soft, molded but partially molten polymeric carrier tiles 2133 are present between the curvature-inducing component plates, such as those 2206, 2208 and being cooled during their travel in cooling tower mechanism 2151, as described above, the already-applied molded replication of natural slate texture, natural tile texture or natural wood texture is not affected or removed, because the forces that are applied to the plates 2206, 2208 in tower 2151 are low enough to prevent removal of such texture. Also the thermoplastic polymeric carrier tiles are already sufficiently cooled/solidified at their surface locations such that such textures are already set but internally the thermoplastic polymeric carrier tiles remain sufficiently soft and hot enough to take on the set applied by the plates 2206, 2208 when cooled. By applying curvature to the polymeric carrier tiles 2133 in this manner, it allows use of flat carrier plates 2127 and allows the use of mold shapes that are easier to work with and are generally less expensive than molds with the arcuate-forming polymeric carrier tile features built into the mold components 2168 and 2178.

While the movement of polymeric carrier tiles 2133 in the cooling tower while sandwiched between plates 2206, 2208 can be as described above, it will be understood that polymeric carrier tile movement through the cooling tower could alternatively be vertical, horizontal or any of various motions or combinations of motions, as may be desired.

With reference to FIGS. 35 and 36, it will be seen that a lower component plate 2206 of the retention mechanism has its upper surface 2209 thereof, concavely configured as is most clearly illustrated in FIG. 36. Similarly, the lower surface of the upper component plate 2208, while being grooved as shown in FIGS. 37 and 39 complementary to the facing surface of the lower component plate 2206, is convexly configured, as is clearly shown in FIG. 37. Additionally, as shown in FIG. 35, the upper surface 2209 of the lower component plate 2206 is slightly dished, or concavely configured, from its left end 2240 to its right end 2241, as shown, ad as may be more clearly seen by reference to the space between surface portions thereof and a straight phantom line 2242 connecting said ends 2240 and 2241, to provide what is preferably a compound curved surface. The compound curve can be adapted to prevent “smiling” of the tiles under weathering or thermal expansion conditions, where there is a capstock and core with different thermal expansion/contraction behaviors.

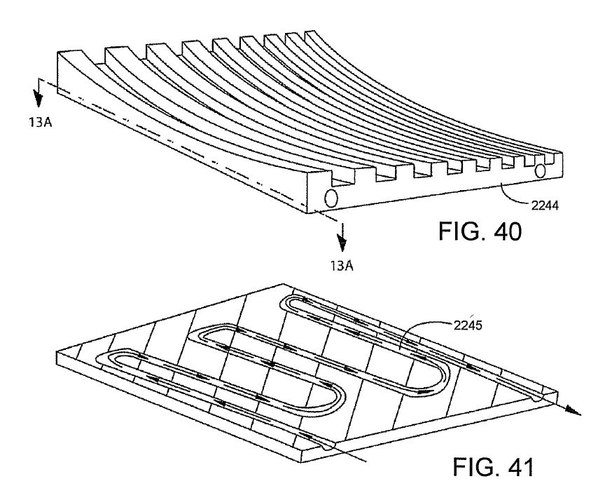

With reference now to FIGS. 40 and 41, an alternative configuration is provided for a lower component plate 2244 of a retention mechanism for sandwiching a polymeric carrier tile therebetween, for providing an alternative mechanism for cooling a polymeric carrier tile carried on the lower component plate 2244. With reference to the section 13A-13A, it can be seen that a circuitous duct configuration 2245 may be provided in the lower component plate 2244, for receipt of a cooling medium, such as a refrigerant therethrough, if desired.

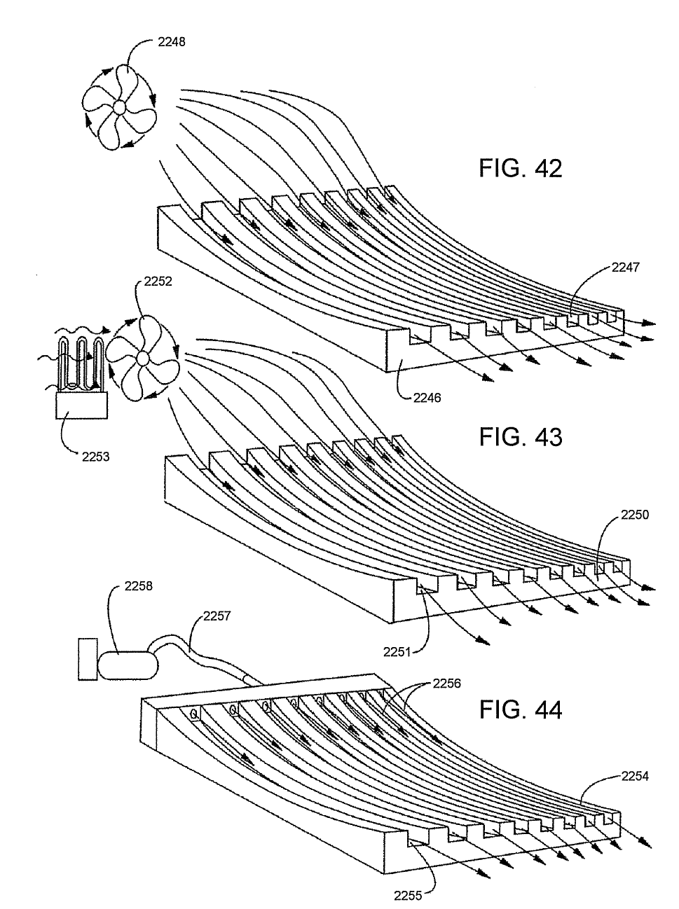

With reference to FIG. 42, another alternative mechanism is provided for cooling a polymeric carrier tile carried on a lower component plate 2246 having grooves 2247 therein, in the form of a fan or the like 2248 delivering a cooling air medium or the like through the grooves 2247, as shown.

With reference to FIG. 43, an illustration similar to that of FIG. 42 is provided, but wherein a lower component plate 2250 having grooves 2251 therein is provided with cool air delivered via a fan 2252 blowing from an air conditioning mechanism 2253 or the like, for providing additional cooling over and above that which would be provided via ambient air, for a polymeric carrier tile carried on the lower component plate 2250.

With reference to FIG. 44, it will be seen that yet another alternative embodiment of a lower component plate 2254 is provided, wherein an alternative refrigerant or the like can be delivered via the grooves 2255 in the plate 2254, in the direction of the arrows 2256, such coolant being a refrigerant or the like delivered via a line 2257, provided via a coolant tank 2258 or the like.

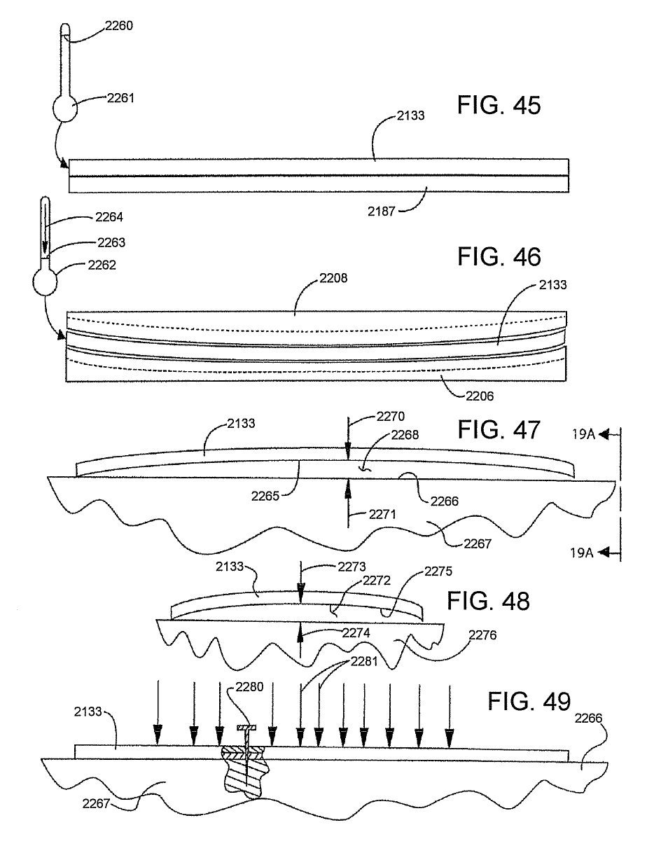

With reference to FIG. 45, there is a representation of a polymeric carrier tile 2133 carried by a secondary plate 2187, prior to it being delivered to a cooling tower, in which a diagrammatic thermometer representation is shown at the left end, indicating that the temperature of the polymeric carrier tile 2133 is still at a relatively high level as shown by the temperature indicia 2260 for the thermometer 2261 thereof.

With reference to FIG. 46, it will be seen that the polymeric carrier tile 2133, upon leaving the cooling tower illustrated in FIG. 33, and being delivered to the station 2210, has been cooled down, such that the diagrammatic representation of a thermometer 2262 shows that the temperature level 2263 indicated thereon has been reduced substantially as indicated by the arrow 2264, so that the polymeric carrier tile is now fully formed and cooled, and substantially rigid in nature.

With reference to FIG. 47, there is a diagrammatic side view representation of the polymeric carrier tile 2133 with its downward-facing concave surface 2265, facing an upper surface 2266 of a roof 2267, prior to being fastened to the roof, showing a spacing 2268 between opposing arrows 2270, 2271, such that the bottom surface of the polymeric carrier tile 2133 is slightly arched and concave above the roof 2267, providing a top-to-bottom arch.

With reference to FIG. 48, it will be seen that, in an end view, the polymeric carrier tile 2133 is dished in end view, as shown by the spacing 2272 between the arrows 2273, 2274, with the bottom surface 2275 of the polymeric carrier tile being slightly arched and concave above the roof 2276, providing a right/left arch.

With reference to FIG. 49, it will be seen that the polymeric carrier tile 2133 is shown fastened down against the upper surface 2266 of the roof 2267 by one or more fasteners 2280 that draw the polymeric carrier tile tightly against the roof in the direction of the several arrows 2281, for secure fastening of the polymeric carrier tile 2133 flatly against the surface 2266 or the roof 2267.

A benefit of the curvature shown at surface 2275 for the polymeric carrier tile 2133 of FIG. 48 is that when fasteners such as those 2280 are applied as shown in FIG. 49 and the polymeric carrier tile 2133 engages against the surfaces 2266 of a roof, the built-in memory of the polymeric carrier tile 2133 of its shape as shown for example in FIG. 28, resists upward edge curl or “smile” that may otherwise result from thermal expansion, weathering, aging or stress relaxation of the polymeric carrier tile. Thus, the curvature of the single as shown in FIG. 48, for example, makes the contact of the polymeric carrier tiles with the roof more secure.

It will be understood that in many instances the mechanisms for effecting movement of the polymeric carrier tiles, the carrier plates, and the like, from one station to the other, are schematically shown, without showing all possible details of conveyors, walking beams, etc., and that other mechanisms may be used. Similarly, with respect to the robot illustrated in FIG. 21, it will be understood that such mechanisms with varying extents of automation are available in the various mechanical arts, and can be used to mechanically move the polymeric carrier tile, carrier plates and the like and that other such mechanisms can be used.

Another aspect of the invention relates to a photovoltaic device, an example of which is shown in schematic cross-sectional view in FIG. 51. Photovoltaic device 2388 includes a photovoltaic element 2310 having a substrate 2389 and a top surface 2314. It also includes a cover element 2330, which substantially covers the photovoltaic element 2310 and is affixed to its top surface 2314. The cover element 2330 is longer and/or wider than the substrate 2389 of the photovoltaic element 2310 by at least about 2 mm. In certain embodiments of the invention, the cover element is longer and/or wider than the substrate by at least about 4 mm, or even at least about 8 mm. In certain embodiments of the invention, the cover element is both longer and wider than the substrate by at least about 2 mm. The cover element can overlap the substrate of the photovoltaic element on both edges of the substrate along the length of the substrate, the width of the substrate, or both (i.e., overlap on all sides). Photovoltaic devices including a cover element affixed to the top surface of a photovoltaic element can be used as a precursor in the manufacture of photovoltaic roofing tiles as described above. For example, as shown in FIG. 51, the cover element 2330 overlaps the photovoltaic element 2310, leaving a peripheral area 2335 of the cover element that can be affixed to a polymeric carrier tile as described above. The photovoltaic device according to this aspect of the invention can also include a polymeric carrier tile disposed adjacent to the peripheral area of the cover element.

The invention is further described by the following non-limiting examples.

### EXAMPLE 1

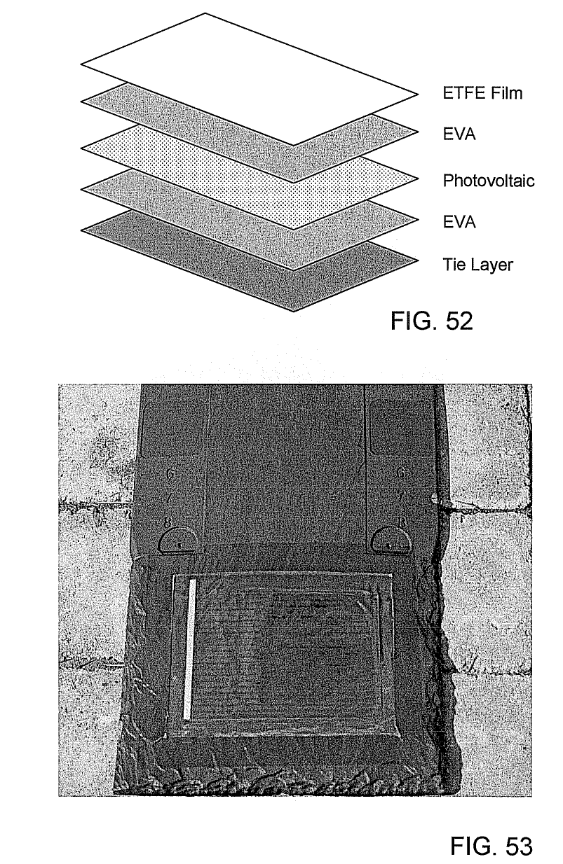

A laminate photovoltaic element having the structure of FIG. 52 was made by vacuum lamination. The structure was constructed by placing an 4 mil ETFE top film (available from Saint-Gobain Corp., Wayne, N.J.) with a cementable side facing the photovoltaic element, a 18 mil EVA encapsulant (available from STR Corp., Enfield, Conn.), a photovoltaic cell (T-Cell available from Uni-Solar, Auburn Hills, Mich.), another film of EVA encapsulant, and a 10 mil tie layer of extruded blend of PP (Basell KS021P) and EVA (Bynel E418 from DuPont Corp). The T-Cell had lateral dimensions of roughly 7.5″×4.75″, and the other laminate sheets had lateral dimensions of roughly 9″×6.25″. Vacuum lamination was performed in model SPI-480 vacuum laminator from Spire Corp. at temperature of 155° C., to form a laminate structure that extended roughly 0.75″ on each side of the T-Cell. The laminate structure was placed on the top surface of a polypropylene polymeric tile preform just prior to the compression molding step, and a thin ETFE release film was placed on top to allow release from the mold. The polypropylene polymeric tile preform had a temperature of approximately 270° F., and was in a soft and pliable state. Immediately upon contact with the hot surface of the polymeric tile preform, the EVA and tie layer of the laminate began to melt, become more clear, and adhere to the preform surface. This assembly was allowed to dwell for 10-20 seconds, and then entered the mold cavity. The mold cavity was as described above with respect to International Patent Application no. PCT/U.S.07/85900, and had lateral dimensions of about 18″×12″. The mold closed, exerting approximately 40 tons pressure on the laminate structure and the polymeric tile preform. The polymeric material of the polymeric tile preform flowed to fill the mold cavity. After 2-3 seconds under pressure, the photovoltaic roofing tile was released from the mold, trimmed, and allowed to cool in a cooling tower. After cooling, the back side of the photovoltaic roofing tile was drilled to expose the electrical contacts on the underside of the photovoltaic element. The photovoltaic roofing tile was exposed to sunlight; a 2.1 V potential difference was measured across the terminals, demonstrating that the compression force used to make the polymeric carrier tile did not cause the photovoltaic element to become inactive. FIG. 53 shows the photovoltaic roofing tile made in this Example. Good bonding was observed between the photovoltaic element, the tie layer and the polypropylene carrier tile.

### EXAMPLE 2

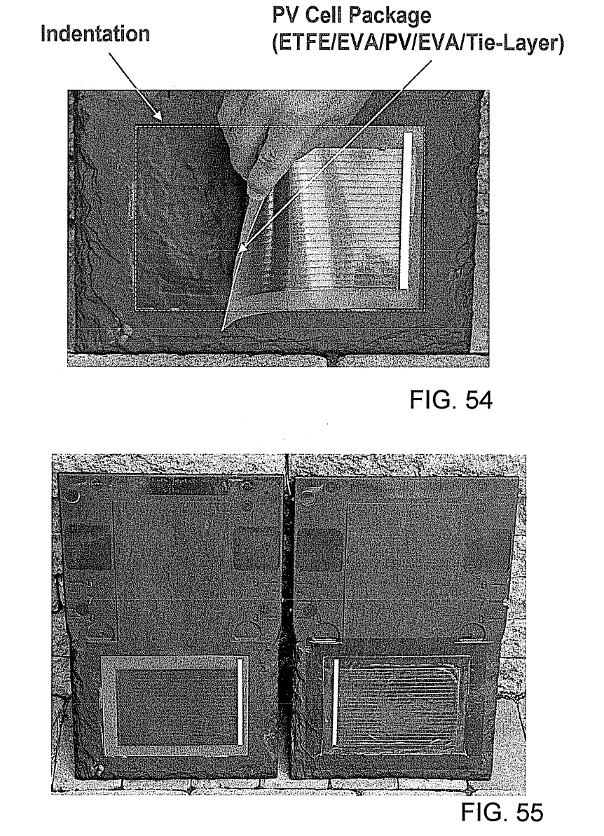

A polymeric carrier tile can be compression molded with an indentation formed in its top surface. For example, a thin (e.g., ˜⅛″) sheet of silicone rubber can be cut to dimensions slightly larger than those of the photovoltaic element (e.g., a laminate having an adhesive bottom later, e.g., as described above in Example 1). The silicon rubber sheet can be placed on the polymeric tile preform, and compression molded into its top surface to form the polymeric carrier tile. The silicone rubber sheet can be removed to leave an indentation sized slightly larger than the photovoltaic element. The photovoltaic element can be placed in the indentation, for example as shown in FIG. 54, and in the left half of FIG. 55. The assembly so formed can be placed on a carrier as described above with respect to International Patent Application no. PCT/US07/85900, then put into an oven hot enough to activate the adhesive. A release film (e.g., ETFE) can be placed over the assembly on the carrier, which can be pressed in a platen press to ensure good contact of the adhesive and optionally press the laminate further into the polymeric carrier tile. The press can be opened and the release film can be removed to form a photovoltaic roofing tile, for example as shown in FIG. 55. In FIG. 55, the outer outline around the photovoltaic element is the outline of the release film. As the skilled artisan will appreciate, the platen press can be appropriately release coated to obviate the use of a separate release film. Alternatively, a photovoltaic laminate (e.g., a laminate having an adhesive bottom later, e.g., as described above in Example 1) can be placed directly on the polymeric perform, covered with a release film made of ETFE and compression molded into the polypropylene tile. In this case, heat from the polymeric perform activates the adhesive layer and bonds the photovoltaic element to the polypropylene tile. If the heat from the polymeric perform or the dwell time in the press is not sufficient enough to fully activate the adhesive layer, the assembly can be secondarily placed in a curing oven for a typical period of between 5 to 15 minutes. FIG. 55 shows two assemblies in which a photovoltaic element is placed in an indentation formed in a polymeric carrier tile, on the left, before a release film made of ETFE is added and the photovoltaic element is affixed to the polymeric carrier tile; and on the right, after the photovoltaic element was affixed and a release film removed.

It will be apparent to those skilled in the art that various modifications and variations can be made to the present invention without departing from the scope of the invention. Thus, it is intended that the present invention cover the modifications and variations of this invention provided they come within the scope of the appended claims and their equivalents.

1. A photovoltaic roofing tile comprising:
a polymeric carrier tile having a top surface and a bottom surface; and
a photovoltaic element affixed to the polymeric carrier tile, the photovoltaic element having a bottom surface and a top surface having an active area.

2. The photovoltaic roofing tile of claim 1, wherein the bottom surface of the photovoltaic element is affixed to the top surface of the polymeric carrier tile.

3. The photovoltaic roofing tile of claim 2, wherein the polymeric carrier tile has an indentation formed in its top surface, and wherein the photovoltaic element is disposed in the indentation.

4. The photovoltaic roofing tile of claim 3, wherein the lateral gap between each edge of the indentation and an edge of the photovoltaic element is less than 100 μm.

5. The photovoltaic roofing tile of claim 3, wherein the top surface of the photovoltaic element is substantially flush with the top surface of the polymeric carrier tile.

6. The photovoltaic roofing tile of claim 2, further comprising a cover element substantially covering the photovoltaic element, wherein the cover element overlaps and is affixed to at least part of the top surface of the polymeric carrier tile.

7. The photovoltaic roofing tile of claim 6, wherein the cover element is sealed to the top surface of the polymeric carrier tile.

8. The photovoltaic roofing tile of claim 2, further comprising an adhesive layer disposed between the bottom surface of the photovoltaic element and the top surface of the polymeric carrier tile.

9. The photovoltaic roofing tile of claim 8, wherein the photovoltaic roofing tile comprises a headlap portion and a butt portion disposed lengthwise with respect to the headlap portion, the butt portion having a length in the range of 0.5-10 times the length of the headlap portion, and wherein the photovoltaic element is affixed to the polymeric carrier tile in the butt portion of the photovoltaic roofing tile.

10. The photovoltaic roofing tile of claim 2, wherein the polymeric carrier tile comprises a core material and a layer of capstock material formed on the core material.

11-12. (canceled)

13. The photovoltaic roofing tile of claim 1, wherein the polymeric carrier tile has an opening formed therein, the top surface of the photovoltaic element includes an inactive area, which is affixed to the bottom surface of the polymeric carrier tile, and the active area of the top surface of the photovoltaic element is substantially aligned with the opening formed in the polymeric carrier tile.

14. (canceled)

15. The photovoltaic roofing tile of claim 13 further comprising a cover element substantially covering the active face of the photovoltaic element, wherein the cover element overlaps and is affixed to at least part of the top surface of the polymeric carrier tile.

16-18. (canceled)

19. The photovoltaic roofing tile of claim 1, further comprising a polymeric overlay having a top surface, a bottom surface and opening formed therein, wherein the top surface of the photovoltaic element includes an inactive area, which is affixed to the bottom surface of the polymeric overlay, and the bottom surface of the photovoltaic element is affixed to the top surface of the polymeric carrier tile, and the active area of the top surface of the photovoltaic element is substantially aligned with the opening formed in the polymeric overlay.

20. (canceled)

21. The photovoltaic roofing tile of claim 19, wherein the photovoltaic element further comprises an electrical lead, which is at least partially disposed between the polymeric overlay and the polymeric carrier tile.

22. The photovoltaic roofing tile of claim 19, wherein the photovoltaic roofing tile further comprises a cover element, which overlaps and is affixed to at least part of the top surface of the polymeric overlay.

23. The photovoltaic roofing tile of claim 22, wherein the cover element is sealed to the top surface of the polymeric overlay.

24. (canceled)

25. A roof comprising one or more photovoltaic roofing tiles of claim 1 disposed on a roof deck.

26. A method of making a photovoltaic roofing tile comprising
a polymeric carrier tile having a top surface and a bottom surface; and
a photovoltaic element having a top surface and a bottom surface, the top surface having an active area, the photovoltaic element being affixed to the polymeric carrier tile,
the method comprising:
inserting into a compression mold
a polymeric tile preform having a top surface and a bottom surface, and
the photovoltaic element, a surface of the photovoltaic element being disposed adjacent to a surface of the polymeric tile preform;
compression molding the polymeric tile preform and the photovoltaic element together to form an unfinished photovoltaic roofing tile; and
finishing the unfinished photovoltaic roofing tile to provide the photovoltaic roofing tile.

27. The method of claim 26, wherein finishing the unfinished photovoltaic roofing tile comprises removing the unfinished photovoltaic roofing tile from the compression mold and allowing the unfinished photovoltaic roofing tile to cool.

28. The method of claim 26, wherein finishing the unfinished photovoltaic roofing tile comprises removing flashing from the edges of the unfinished photovoltaic roofing tile.

29. (canceled)

30. The method of claim 26, wherein the photovoltaic element is inserted into the compression mold so that its bottom surface is disposed adjacent to the top surface of the polymeric tile preform, and wherein during the compression molding the bottom surface of the photovoltaic element is affixed to the top surface of the polymeric carrier tile.

31. The method of claim 30, wherein during the compression molding, the photovoltaic element is at least partially embedded in the top surface of the polymeric carrier tile.

32. The method of claim 30, wherein an adhesive layer is inserted into the compression mold between the bottom surface of the photovoltaic element and the top surface of the polymeric carrier tile.

33. The method of claim 30, wherein the adhesive layer is joined to the photovoltaic element and/or the polymeric carrier tile before it is inserted into the compression mold.

34. The method of claim 30, wherein a cover element is inserted into the compression mold adjacent to the top surface of the photovoltaic element, and wherein during the compression molding step, the cover element is affixed to at least part of the top surface of the polymeric carrier tile.

35. (canceled)

36. The method of claim 26, wherein
the top surface of the photovoltaic element has an inactive area, wherein the polymeric tile preform has an opening formed therein, with which the active area of the top surface of the photovoltaic element is substantially aligned;
the photovoltaic element is inserted into the compression mold so that the inactive area of its top surface is disposed adjacent to the bottom surface of the polymeric tile preform and the active area of its top surface is substantially aligned with the opening in the polymeric tile preform; and
during the compression molding the inactive area of the top surface of the photovoltaic element is affixed to the bottom surface of the polymeric carrier tile.

37. The method of claim 36, wherein during the compression molding, the photovoltaic element is at least partially embedded in the bottom surface of the polymeric carrier tile.

38-40. (canceled)

41. The method of claim 26, wherein
the top surface of the photovoltaic element has an inactive area;
the photovoltaic roofing tile further comprises a polymeric overlay, the polymeric overlay having an opening formed therein with which the active area of the top surface of the photovoltaic element is substantially aligned;
the photovoltaic element is inserted into the compression mold so that the inactive area of its top surface is disposed adjacent to the bottom surface of a polymeric overly preform, the polymeric overlay preform having an opening formed therein, and so that its bottom surface is disposed adjacent to the top surface of the polymeric tile preform; and
during the compression molding the inactive area of the top surface of the photovoltaic element is affixed to the bottom surface of the polymeric overlay, and the bottom surface of the photovoltaic element is affixed to the top surface of the polymeric carrier tile.

42. (canceled)

43. The method of claim 41, wherein a cover element is inserted into the compression mold adjacent to the top surface of the photovoltaic element, and wherein during the compression molding step, the cover element is affixed to at least part of the top surface of the polymeric overlay.

44. The method of claim 41, wherein a cover element is inserted into the compression mold between the top surface of the photovoltaic element and the bottom surface of the polymeric overlay, and wherein during the compression molding step, the cover element is affixed to at least part of the bottom surface of the polymeric overlay.

45. The method of claim 26, wherein the surface of the polymeric tile preform adjacent to which the photovoltaic element is disposed is in a softened state when the photovoltaic element is disposed adjacent to it and during the compression molding step.

46. The method of claim 26, wherein the photovoltaic element has an adhesive layer at the surface to be affixed to the polymeric carrier tile.

47. The method of claim 26, wherein compression molding step is performed under vacuum.

48. A method of making a photovoltaic roofing tile comprising
a polymeric carrier tile having a top surface and a bottom surface, one of the surfaces having an indentation formed therein; and
a photovoltaic element having a top surface and a bottom surface, the top surface having an active area, the photovoltaic element being affixed to the polymeric carrier tile and disposed in the indentation therein,
the method comprising:
inserting into a compression mold a polymeric tile preform having a top surface and a bottom surface;
compression molding the polymeric tile preform to form a polymeric carrier tile having the indentation disposed in one of the surfaces;
disposing the photovoltaic element in the indentation; and
affixing the photovoltaic element to the polymeric carrier tile to provide the photovoltaic roofing tile.

49. A photovoltaic device comprising:
a photovoltaic element having a substrate and a top surface; and
a cover element substantially covering the photovoltaic element and affixed to the top surface of the photovoltaic element,
wherein the cover element is longer and/or wider than the substrate of the photovoltaic element by at least about 1 mm.
